(19) United States
(12) Patent Application Publication
(10) Pub. No.: US 2026/0278968 A1
(43) Pub. Date: Sep. 17, 2026

(54) Automated Building Image Modification To Include Added Objects Of Defined Sizes

(71) Applicant: MFTB Holdco, Inc., Seattle, WA (US)

(72) Inventor: Jasmine Jayant Bhanushali, Bothell, WA (US)

(21) Appl. No.: 18/885,375

(22) Filed: Sep. 13, 2024

(51) Int. Cl. G06T 19/20; G06F 30/13; G06T 7/00; G06T 7/55; G06T 7/62; G06T 7/73; G06T 15/00; G06T 15/50

(52) U.S. Cl. CPC G06T 19/20; G06F 30/13; G06T 7/0002; G06T 7/55; G06T 7/62; G06T 7/75; G06T 15/005; G06T 15/506; G06T 2200/24; G06T 2207/20081; G06T 2207/20084; G06T 2207/20092; G06T 2207/30244; G06T 2210/04; G06T 2219/2016

(57) ABSTRACT

Techniques are described for using computing devices to perform automated operations for modifying a source image acquired at a building to add a target object of a defined size without using a 3D object model of the target object, and using the modified source image in an automated manner. The techniques may include determining a group of pixels within the source image with a size and shape corresponding to the target object's actual 3D size using image-specific dimensions of parts of the building visible in the source image (e.g., using a floor plan of the building and dimensions for a visible room), determining positioning within the source image for the group of pixels, generating and supplying conditioning information to a trained machine learning diffusion model including a pixel mask at contiguous pixel locations for the positioned pixel group within the source image, and displaying the modified source image.

### TECHNICAL FIELD

The following disclosure relates generally to techniques for automatically modifying a source image acquired at a building to add one or more objects of defined sizes based in part on image-specific dimensions of parts of the building that are visible in the source image and without using a three-dimensional object model, such as to use image-specific building dimensions within the visual data of a source image to determine a group of pixels within the source image having a size and shape that correspond to the actual size and shape of an object to be added, and to use a trained machine learning diffusion model to add the object at its actual size within a modified version of the source image to reflect determined positioning of the group of pixels within the source image.

### BACKGROUND

In various circumstances, such as architectural analysis, property inspection, real estate acquisition and development, general contracting, improvement cost estimation, etc., it may be desirable to know the interior of a house or other building without physically traveling to and entering the building. However, it can be difficult to effectively capture, represent and use such building interior information, including to identify buildings that satisfy criteria of interest, and to display visual information captured within building interiors to users at remote locations (e.g., to enable a user to understand the layout and other details of the interior, including to control the display in user-selected manners). Also, even if a user is present at a building, it can be difficult to effectively navigate the building and determine information about the building that is not readily apparent. While a floor plan of a building may provide some information about layout and other details of a building interior, such use of floor plans has some drawbacks, including that floor plans can be difficult to construct and maintain, to accurately scale and populate with information about room interiors, to visualize and otherwise use, etc. In addition, it can be difficult to visualize changes to an existing building interior.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1B include diagrams depicting an exemplary building interior environment and computing system(s) for use in embodiments of the present disclosure, including to generate and present information representing an interior of the building based in part on determined building dimension data.

FIGS. 2A-2L illustrate examples of automatically modifying a source image acquired at a building to add one or more target objects of defined sizes based in part on image-specific dimensions of parts of the building visible in the source image.

FIG. 3 is a block diagram illustrating computing systems suitable for executing an embodiment of a system that performs at least some of the techniques described in the present disclosure.

FIGS. 4A-4B illustrate an example embodiment of a flow diagram for a Building Image Modification Manager (BIMM) system routine in accordance with an embodiment of the present disclosure.

FIG. 5 illustrates an example embodiment of a flow diagram for a Building Information Access system routine in accordance with an embodiment of the present disclosure.

### DETAILED DESCRIPTION

The present disclosure describes techniques for using computing devices to perform automated operations involving automatically modifying a source image acquired at a building to add a target object of a defined size by using image-specific dimensions of parts of the building visible in the source image and without using a three-dimensional object model of the target object (e.g., if the three-dimensional, or 3D, object model of the target object is not available), and for subsequently using the modified source image in one or more automated manners. In at least some embodiments, the techniques including adding a target object of a defined size in a modified version of a source image by first determining a group of pixels within the source image that have a size and shape corresponding to the actual size of the target object if the target object was present in the visual data of the source image, such as to determine one or more quantities of pixels within the source image each corresponding to a dimension of a visible structural element of known size (e.g., a wall height or width, a window height or width, etc.), and to adjust at least one such determined quantity of pixels for the visible structural element to reflect a revised quantity of pixels representing the actual size of a corresponding dimension of the target object (e.g., a width or height of a face of the target object that is parallel to a wall structural element if the target object is placed on or adjacent to that wall)—in some such embodiments and situations, the determining of the image-specific building dimensions within the visual data of the source image includes using a defined floor plan of the building that has dimensions for a room visible in the source image and includes a position within the room at which the source image was acquired (i.e., the source image's acquisition location). After determining the size and shape of the group of pixels, the techniques further include determining a position within the source image for the group of pixels, to represent contiguous pixel locations within the source image at which the target object will be added—in at least some embodiments and situations, positioning of the group of pixels is based at least in part on input received from a user (e.g., via a GUI, or graphical user interface, showing the source image and the group of pixels), such as from a user who initiated the modifying of the source image by indicating the source image and the target object to be added. After the positioning of the group of pixels within the source image is determined, the techniques may further include generating conditioning information and supplying it to a trained machine learning diffusion model (e.g., a ControlNet diffusion model) along with the source image to cause the diffusion model to generate the modified version of the source image with the target object having its actual size and shape within the source image at locations corresponding to the positioned group of pixels (e.g., by inpainting a visual representation of the target object), such as by generating a conditional control image having a same size as the source image and with a pixel mask at the contiguous locations for the positioned group of pixels, and supplying the conditional control image and an image of the target object to the diffusion model as conditioning information. After the modified version of the source image with the added target object is generated, the modified version of the source image may be displayed and/or otherwise used in one or more automated manners. Additional details are included below regarding automatically modifying a source image acquired at a building to add a target object of a defined size by using image-specific dimensions of parts of the building visible in the source image and without using a three-dimensional object model of the target object, and some or all techniques described herein may, in at least some embodiments, be performed via automated operations of a Building Image Modification Manager (“BIMM”) system, as discussed further below.

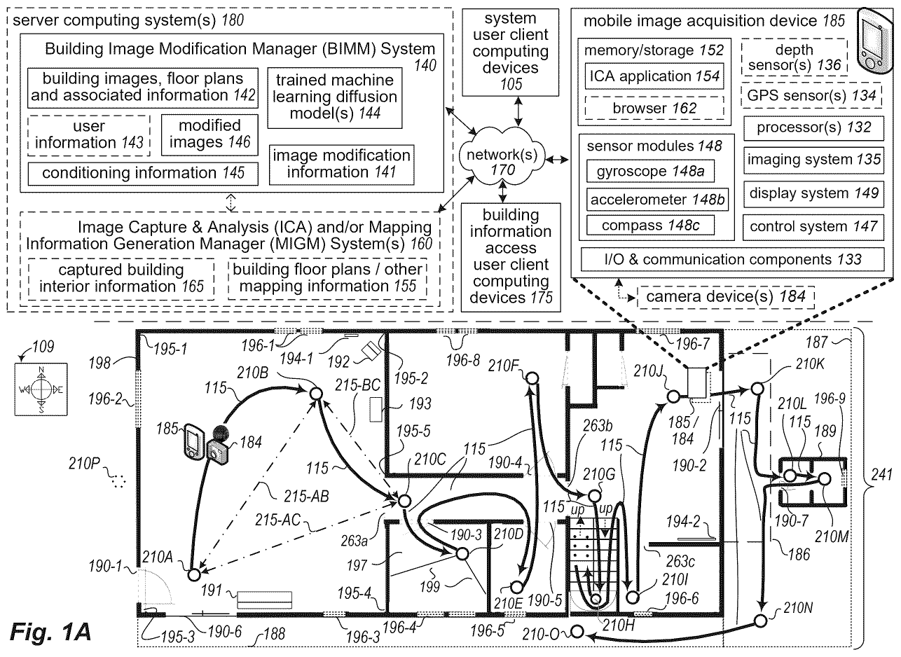

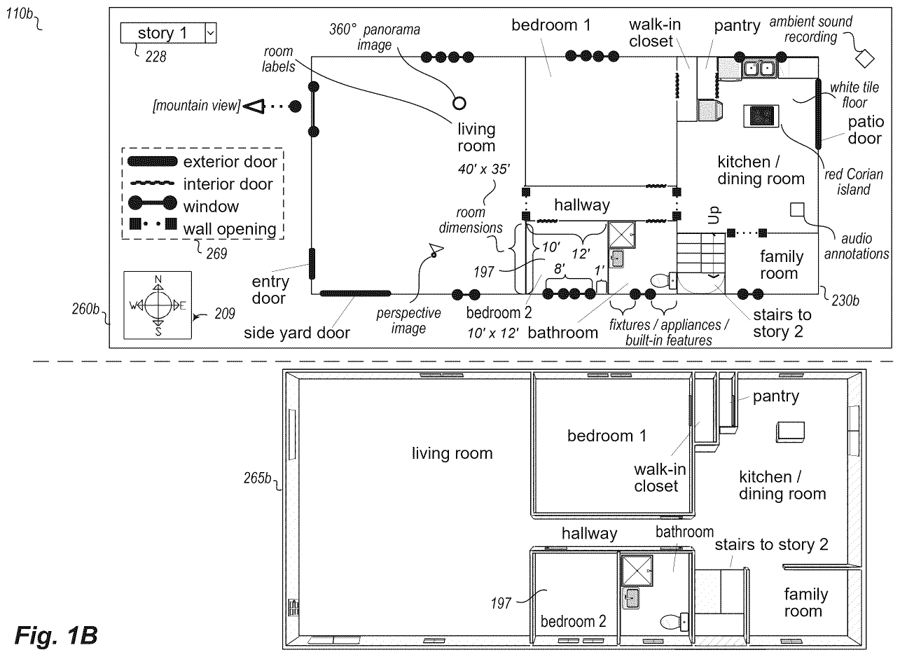

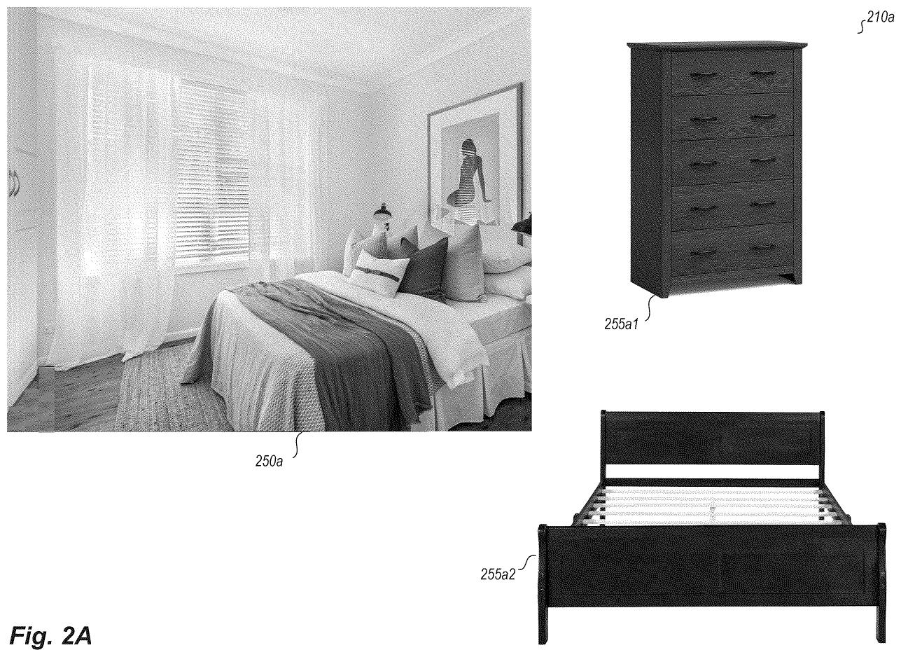

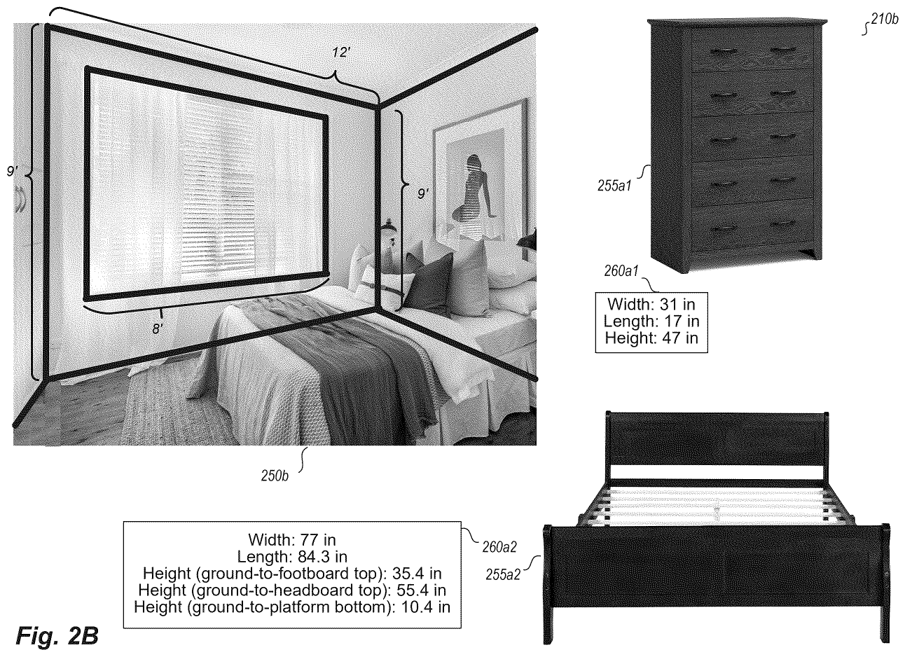

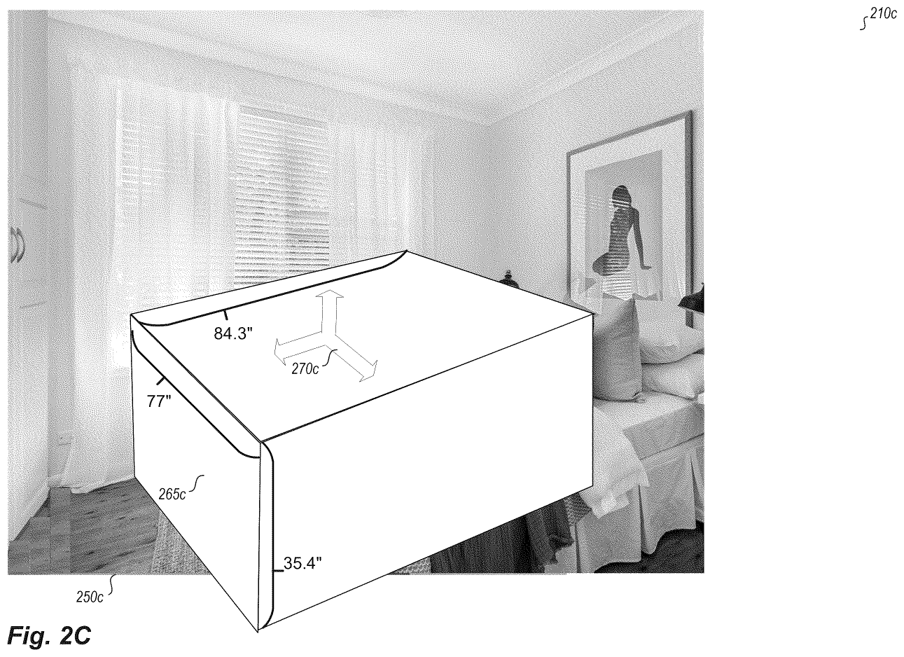

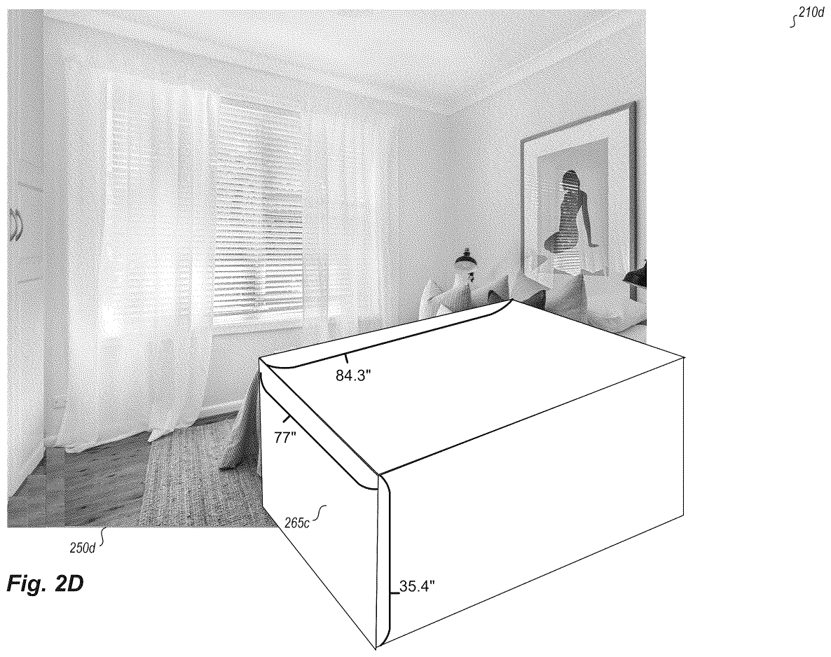

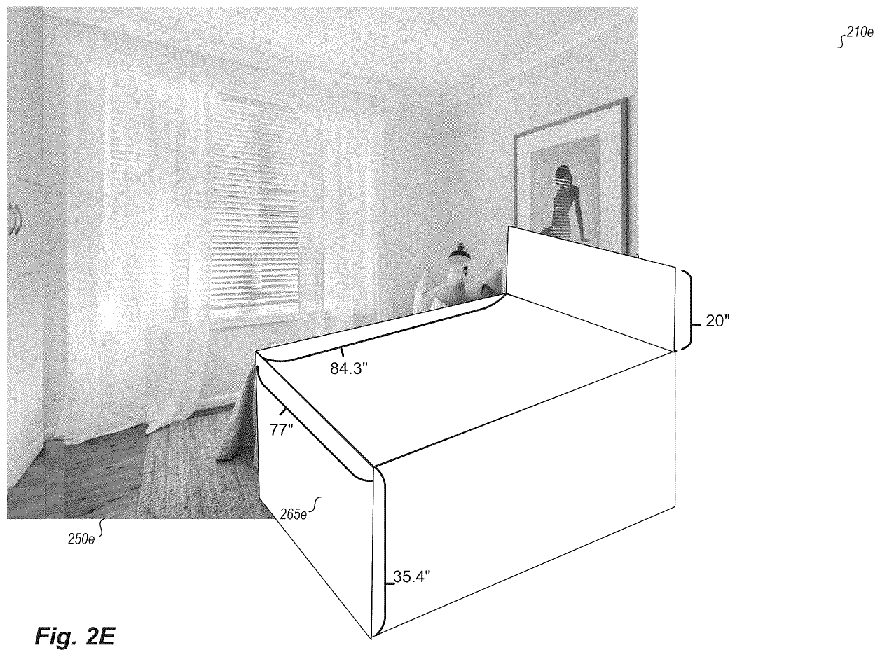

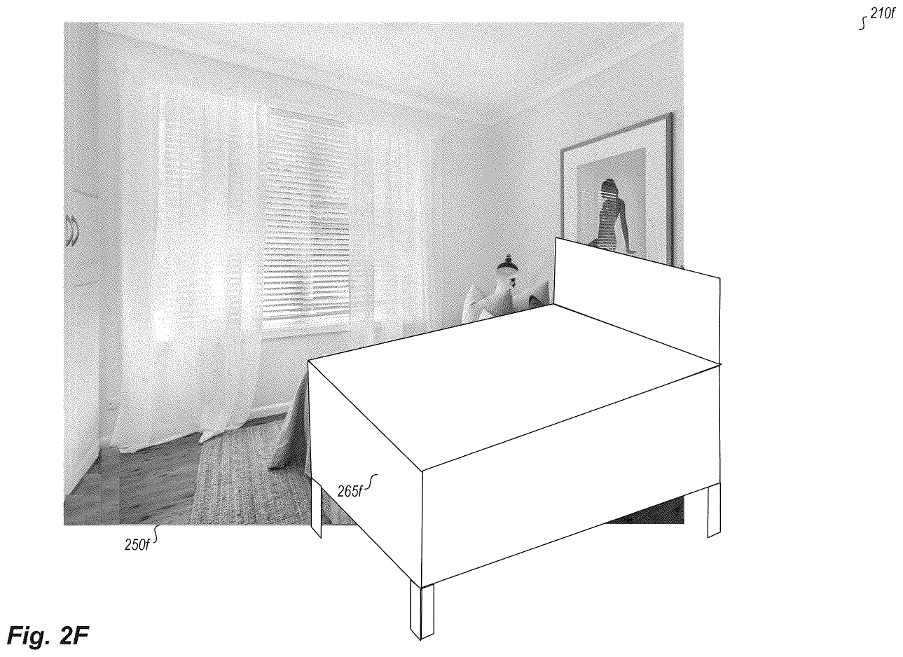

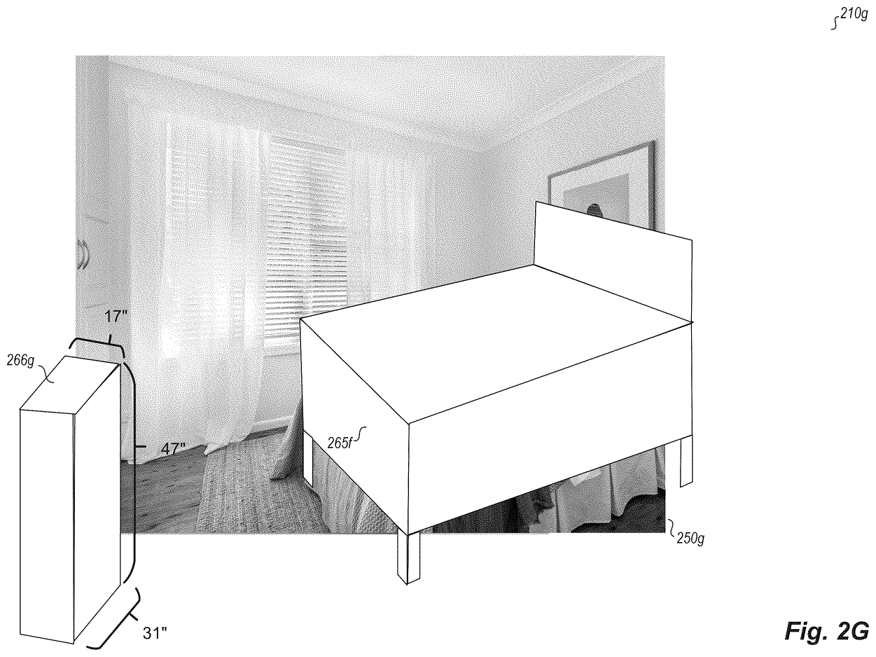

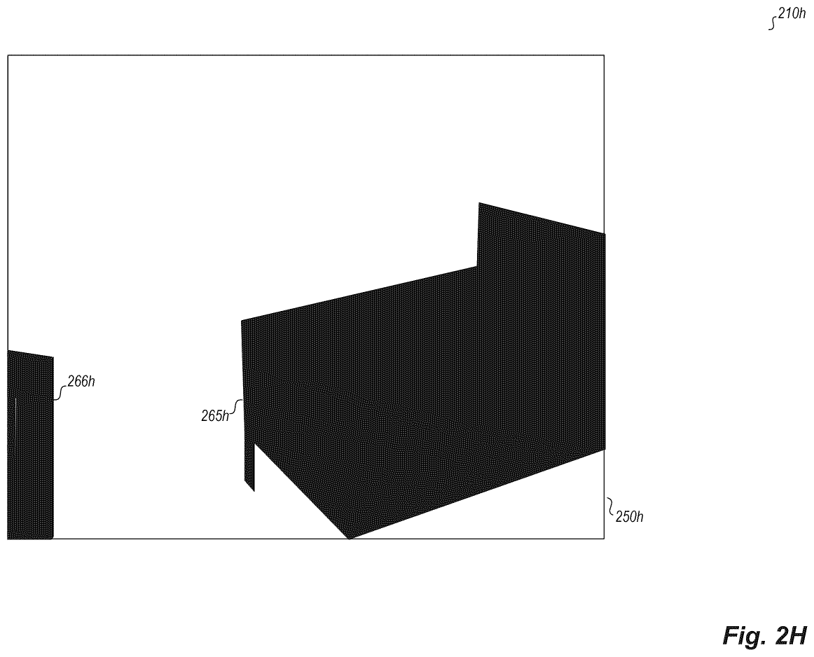

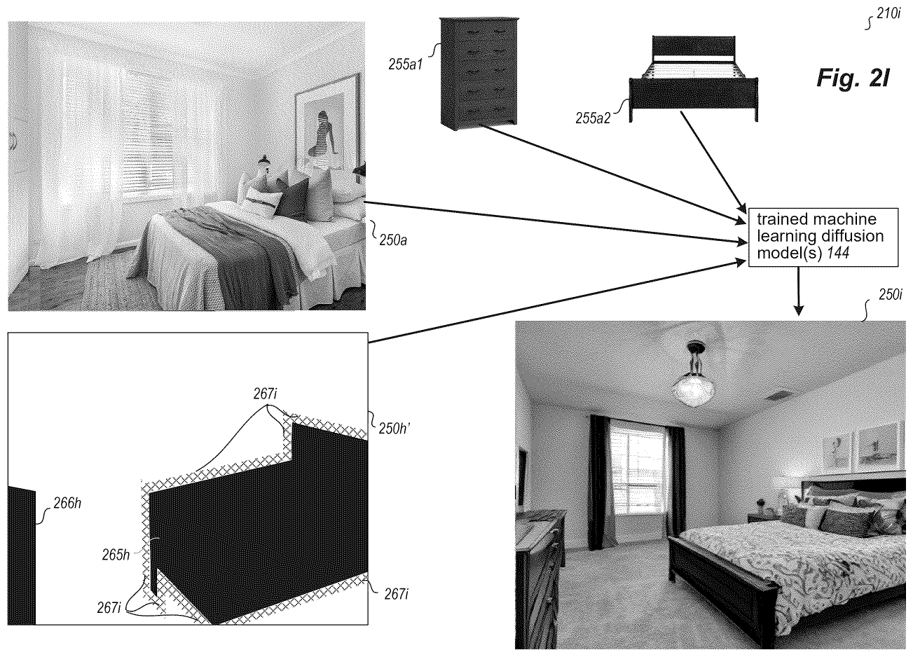

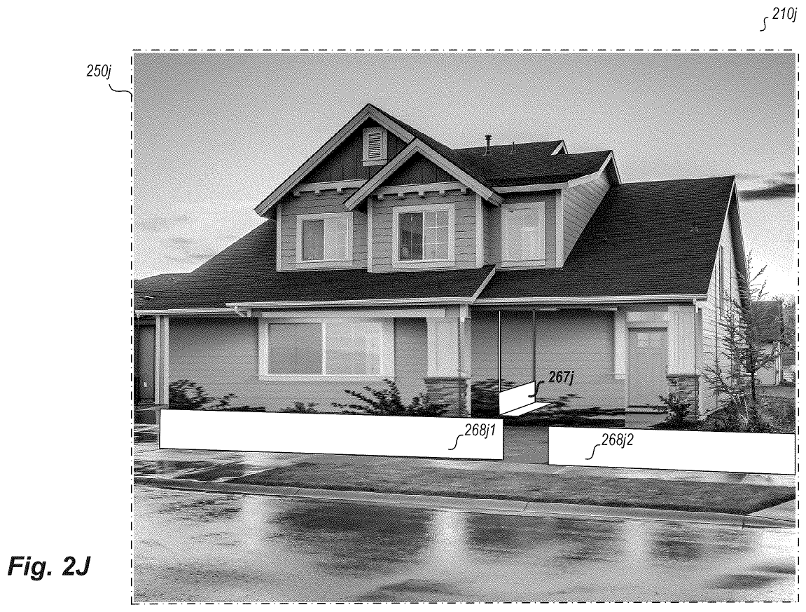

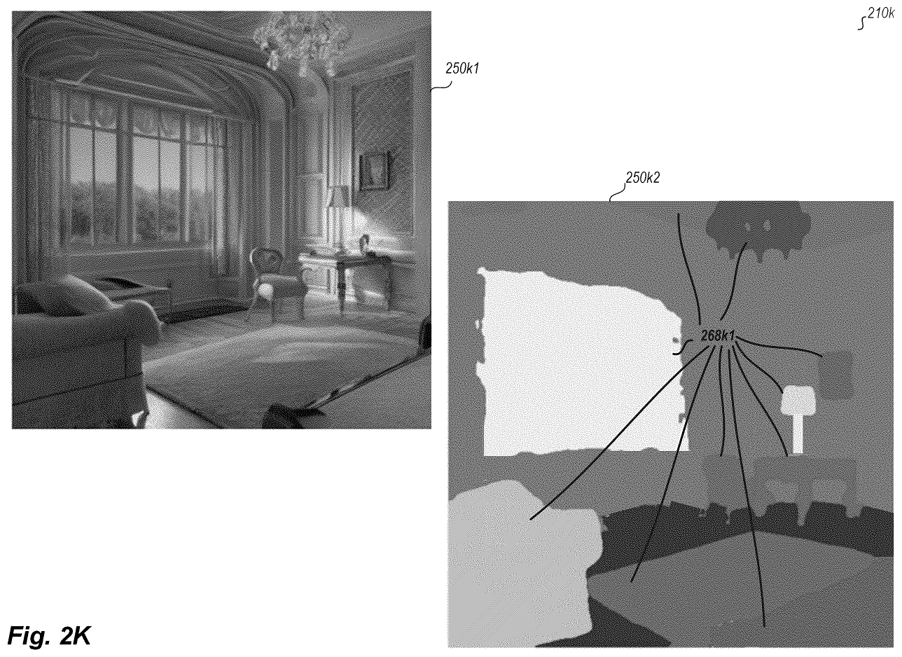

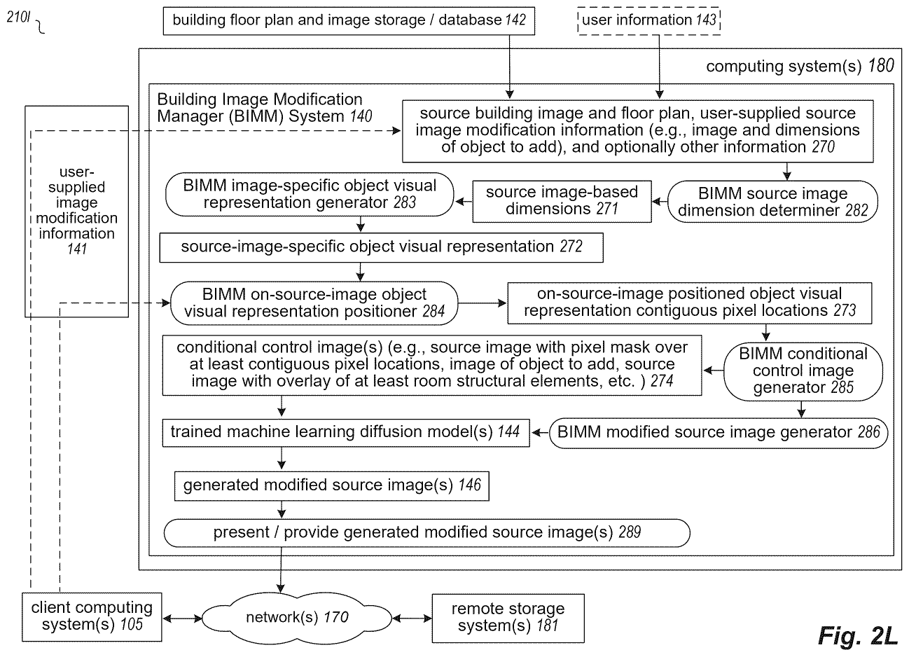

As noted above, in at least some embodiments and situations, the techniques include adding one or more target objects each having a defined size in a modified version of a source image based in part on determining and using image-specific dimensions of parts of the building that are visible in the source image, such as by using a defined floor plan of the building that includes dimensions for a room visible in the source image and includes a position within the room at which the source image was acquired (i.e., the source image's acquisition location). Such a floor plan may, in at least some embodiments, be for an as-built multi-room building (e.g., a house, office building, etc.) and in some situations generated from or otherwise associated with panorama images or other images (e.g., rectilinear perspective images) acquired at acquisition locations in and around the building (e.g., without having or using information from any depth sensors or other distance-measuring devices about distances from an image's acquisition location to walls or other objects in the surrounding building). The floor plan for a building may include determined dimensions of structural elements of rooms in the building, such as a room's length and width and optionally height corresponding to structural elements including the walls and the floor, as well as optionally including dimensions for and locations of other structural elements (e.g., windows, doorways, built-in structures, etc.) and/or other objects in the room (e.g., installed fixtures, appliances, cabinets, switches and other controls, etc.), as well as positions on the floor plan showing the acquisition locations of images associated with the floor plan (e.g., images from which the floor plan is generated and/or other images acquired after the floor plan generation that are localized to the floor plan), and with non-exclusive examples of such a floor plan being illustrated in FIG. 1B and discussed in greater detail below. In other embodiments and situations, the determining of image-specific dimensions of parts of the building that are visible in the source image may be performed in other manners, whether in addition to or instead of using a floor plan of the building, such as based on analyzing visual data of an image (e.g., to detect one or more objects of known sizes, and to extrapolate those known sizes within the source image pixels to other parts of building visible in the source image) and/or using depth data associated with the source image (e.g., for an ‘RGBD’ image with RGB color pixel visual data and associated depth data for each pixel that is captured concurrently with the capture of the visual data, by estimating depth data from analysis of the visual data after the visual data is captured, etc.). Additional details are included elsewhere herein related to determining image-specific dimensions of parts of the building that are visible in a source image, including with respect to the examples of FIGS. 2A-2L.

In addition, as noted above, the techniques may in at least some embodiments and situations include determining a group of pixels within the source image that have a size and shape corresponding to the actual 3D size of a target object if the target object was present in the visual data of the source image. The actual 3D size of the target object (e.g., length, width and height) may be determined in various manners in various embodiments, with non-exclusive examples including the following: receiving an image of a target object and the actual 3D size of the target object from a user, such as a user who indicates the source image and initiates the generating of the modified version of the source image; receiving an image of a target object from a user but not the actual 3D size of the target object, and automatically determining the actual 3D size by performing object identification to identify a unique type of the object (e.g., a model number and manufacturer) or a unique object (e.g., a well-known sculpture) and retrieving actual 3D size information for the identified object and/or an instance of the identified object type; receiving a textual description of a target object and the actual 3D size of the target object from a user, and optionally automatically retrieving an image of the target object (based on a described unique object type and/or object) for subsequent use in the generating of the modified version of the image; etc. The shape of the group of pixels to represent the target object's size and shape may also be determined in various manners in various embodiments, with non-exclusive examples including the following: generating a bounding ‘box’ for the target object that is a geometrical shape (e.g., a cube or other regular prism, a cylinder, a pyramid, a triangular prism, etc.) and that encloses the actual size and shape of the target object, with the ‘box’ in bounding box being a term of art that is not limited to regular prisms; generating multiple connected and/or adjacent bounding boxes for the target object each having its own geometrical shape (e.g., two regular prisms of different sizes and/or shapes, a regular prism and a different geometrical shape, etc.); generating a 3D outline of the target object (e.g., a non-uniform shape that is not a geometrical shape), such as by analyzing an outline of the target object in one or more images of it and creating a representative 3D shape for it; etc. The size of the group of pixels to represent the target object's size and shape may be determined based on the dimensions within the source image of its visual data, such as to determine quantities of pixels in the source image that correspond to a dimension of a structural element visible in the source image (e.g., for a ‘straightened’ image in which a vertical element in the room is represented within the same pixel column, such as an inter-wall border or side of a window or a side of a doorway, to determine a quantity of pixels within a given pixel column that correspond to an actual height of a structural element in the room that is straight in the vertical direction)—it will be appreciated that different columns within a straightened source image will have differing quantities of pixel for a given size in the room based on the distance of the image's acquisition location to the structural element shown in that pixel column, and that similar pixel quantities may be determined for length and width within the source image. Additional details are included elsewhere herein related to determining a group of pixels within the source image that have a size and shape corresponding to the actual 3D size of a target object if the target object was present in the visual data of the source image, including with respect to the examples of FIGS. 2A-2L.

As is also noted above, the techniques may in at least some embodiments and situations include determining a position within the source image for the group of pixels representing a target object's 3D size and shape, to correspond to contiguous pixel locations within the source image at which the target object will be added. In at least some embodiments and situations, positioning of the group of pixels is based at least in part on input received from a user (e.g., via a GUI showing the source image and the group of pixels), such as to enable the user to move the group of pixels within the source image but to not manually change the size or shape of the group of pixels, although the size and/or shape of the group of pixels may be automatically modified when moved to different positions within the source image to reflect different quantities of pixels corresponding to a given size within a visible room at different positions in the source image (e.g., based on distance from the source image's acquisition location to a part of the room shown in a portion of the source image and/or based on an angle of a structural element's surface to the source image's acquisition location). In addition, in some embodiments and situations, the shape and shape of the group of pixels may be determined to reflect an orientation of the target object within the source image that matches orientations of one or more structural elements visible in the source image (e.g., parallel or perpendicular to surfaces of the floor, of one or more walls, etc.), and the user manipulation of the group of pixels may optionally include changing the orientation of the group of pixels within the source image (e.g., with the size and/or shape of the group of pixels being automatically modified to reflect a changing orientation), while in other embodiments and situations such orientation may not be user-manipulatable (e.g., to have a bottom of the target object be adjacent to and level with the floor if the target object is designed to rest on the floor; to have a surface or face of the target object be adjacent to and parallel with another surface of a structural element and/or existing object visible in the source image, such as if the target object is designed to hang on a wall or rest atop another object; for a target object with a shape that is substantially a regular prism, to otherwise have surfaces or faces of the target object be parallel to surfaces of adjacent or nearby structural elements; etc.). Additional details are included elsewhere herein related to determining a position within the source image for the group of pixels representing a target object's 3D size and shape, including with respect to the examples of FIGS. 2A-2L.

As noted above, the techniques may in at least some embodiments and situations include, after the positioning of the group of pixels within the source image is determined, generating conditioning information and supplying it to a trained machine learning diffusion model along with the source image to cause the diffusion model to generate the modified version of the source image with the target object having its actual size and shape within the source image at location(s) corresponding to the positioned group of pixels—such conditioning information is additional input to further control operations of the diffusion model (e.g., along with optional textual prompt instructions) and optionally having various forms in various use cases (e.g., semantic masks, Canny edges, user sketching, human poses, depth, etc.). The diffusion model may have various architectures and/or forms in various embodiments, including in at least some such embodiments to use a ControlNet diffusion model neural network architecture having a locked copy of weights of an original pretrained diffusion model and a separate trainable copy of the weights of at least the encoder portions of the trained diffusion model, to enable the trainable copy to be further trained to support a specific domain and/or use case-in such embodiments, the trainable copy may be further trained to add a target object of a specified 3D size within a source image by using the positioning of a pixel mask to represent the position and size of the target object to be added, and optionally to further use an image of the target object to be added, such as by using at least pairs of training images that include an image with a pixel mask and another image of an object to be added in place of the pixel mask (e.g., in a separate image that is the same size and shape as the image with the pixel mask, in the same image with the pixel mask that includes other visual data, etc.). Additional details related to ControlNet diffusion models are included in “Adding Conditional Control To Text-To-Image Diffusion Models” by Zhang et al., Nov. 26, 2023, accessible at https://arxiv.org/abs/2302.05543, and which is incorporated herein by reference in its entirety. In at least some such embodiments, the generated conditioning information includes one or more conditional control images that are input to the trained diffusion model, optionally along with the source image and/or an image of each of one or more target objects to be added-non-exclusive examples of such conditional control images include the following: an image having a same size and shape as the source image and having a pixel mask at the contiguous locations for the positioned group of pixels (e.g., a binary pixel mask in which each of the values of the pixels in the mask is one of a 0 value or a 1 value, and in which the values of the other pixels outside the mask are the other of the 0 or 1 value); a copy of the source image having such a pixel mask at the contiguous locations for the positioned group of pixels; an image having a same size and shape as the source image and having an overlay to show positions of determined structural elements (e.g., a wire frame outline of structural elements such as walls, a floor, a ceiling, windows, doorways, etc.), whether overlaid on the source image or on an otherwise blank image; an image having a same size and shape as the source image and having an overlay to show positions of lighting sources (e.g., windows, lights, etc.), whether overlaid on the source image or on an otherwise blank image; etc. In addition, in at least some embodiments, the pixel mask used in at least some conditioning information may be further modified to use non-binary values (e.g., values between 0 and 1) for at least some pixels that are adjacent to or otherwise near the positioned group of pixels (e.g., surrounding the positioned group of pixels in whole or in part), with such additional pixels with non-binary values referred to herein as a partial pixel mask, and with the diffusion model being further trained to retain original pixels of the source image under the partial pixel mask but to add shading for those original pixels based on the introduction of the added target object for the positioned group of pixels and in light of the light source(s) providing illumination for the source image, although the positioning of the light source(s) may not be supplied to the trained diffusion model in at least some embodiments and situations (e.g., with the model learning to automatically add shadowing in appropriate areas based on our illumination levels within the image). Additional details are included elsewhere herein related to generating and using conditioning information as input to a trained machine learning diffusion model to cause generation of the modified version of the source image with the target object having its actual size and shape within the source image at location(s) corresponding to the positioned group of pixels, including with respect to the examples of FIGS. 2A-2L.

The described techniques provide various benefits in various embodiments, including to add one or more indicated target objects with defined 3D sizes to a source image having visual data of a portion of a multi-room building without using three-dimensional object models of the target objects, and to further in some situations use an existing floor plan of the building to determine image-specific dimensions within the visual data of the source image—in this manner, more accurate modified source images are generated, in which the size of an added target object is precisely controlled based on use of pixel masks and other conditioning information that is generated and provided to a trained diffusion machine learning model. Such described techniques further provide benefits in generating the modified source images more efficiently (e.g., using less computing resources) via the use of the generated conditioning information. In addition, in some embodiments the described techniques may be used to provide an improved GUI in which a user may more accurately and quickly obtain and use building information that includes such modified source images, including in response to search requests, as part of providing personalized information to the user, as part of providing value estimates and/or other information about a building to a user, etc. Various other benefits are also provided by the described techniques, some of which are further described elsewhere herein.

For illustrative purposes, some embodiments are described below in which specific types of information are acquired, used and/or presented in specific ways for specific types of structures and by using specific types of devices-however, it will be understood that the described techniques may be used in other manners in other embodiments, and that the invention is thus not limited to the exemplary details provided. As one non-exclusive example, while specific types of data structures (e.g., floor plans, adjacency graphs, vector embeddings, etc.) are generated and used in specific manners in some embodiments, it will be appreciated that other types of information to describe floor plans and other associated information may be similarly generated and used in other embodiments, including for buildings (or other structures or layouts) separate from houses, and that floor plans identified as matching specified criteria may be used in other manners in other embodiments. As another non-exclusive example, while specific types of images are described as being modified in specific manners in some embodiments, it will be appreciated that other types of image modifications may be performed in other manners in other embodiments. In addition, the term “building” refers herein to any partially or fully enclosed structure, typically but not necessarily encompassing one or more rooms that visually or otherwise divide the interior space of the structure-non-limiting examples of such buildings include houses, apartment buildings or individual apartments therein, condominiums, office buildings, commercial buildings or other wholesale and retail structures (e.g., shopping malls, department stores, warehouses, etc.), supplemental structures on a property with another main building (e.g., a detached garage or shed on a property with a house), etc. The term “acquire” or “capture” as used herein with reference to a building interior, acquisition location, or other location (unless context clearly indicates otherwise) may refer to any recording, storage, or logging of media, sensor data, and/or other information related to spatial characteristics and/or visual characteristics and/or otherwise perceivable characteristics of the building interior or subsets thereof, such as by a recording device or by another device that receives information from the recording device. As used herein, the term “panorama image” may refer to a visual representation that is based on, includes or is separable into multiple discrete component images originating from a substantially similar physical location in different directions and that depicts a larger field of view than any of the discrete component images depict individually, including images with a sufficiently wide-angle view from a physical location to include angles beyond that perceivable from a person's gaze in a single direction. The term “sequence” of acquisition locations, as used herein, refers generally to two or more acquisition locations that are each visited at least once in a corresponding order, whether or not other non-acquisition locations are visited between them, and whether or not the visits to the acquisition locations occur during a single continuous period of time or at multiple different times, or by a single user and/or device or by multiple different users and/or devices. In addition, various details are provided in the drawings and text for exemplary purposes, but are not intended to limit the scope of the invention. For example, sizes and relative positions of elements in the drawings are not necessarily drawn to scale, with some details omitted and/or provided with greater prominence (e.g., via size and positioning) to enhance legibility and/or clarity. Furthermore, identical reference numbers may be used in the drawings to identify the same or similar elements or acts.

FIGS. 2A-2L illustrate examples of automatically modifying a source image acquired at a building to add one or more target objects of defined sizes based in part on image-specific dimensions of parts of the building visible in the source image and without using a three-dimensional object model of the target object.

In particular, FIG. 2A illustrates information 210a that includes an example source image 250a, such as to correspond to room 197 illustrated in the example floor plans 230b and 265b of FIG. 1B—in this example, the image shows part of a bedroom of a house, including a bed, an exterior wall with a window, and portions of two adjacent walls, the floor and the ceiling. In this example, a user (not shown) desires to add one or more target objects to a modified version of the source image, and selects or otherwise indicates the source image (e.g., from a plurality of images, not shown, captured at the building and stored in a manner accessible to the BIMM system), as well as supplies example images 255a1 and 255a2 corresponding to two example target objects, which in this example are a particular bedroom dresser and a particular bedframe (e.g., a larger king-size bed than the current smaller bed shown in the source image).

FIG. 2B continues the example of FIG. 2A, and illustrates information 210b showing activities of the BIMM system in performing automated operations as preparation for modifying the source image 250a to add the indicated target objects. In particular, the BIMM system first obtains information about sizes of the target objects, so that visual representations of the target objects that are added to the modified version of the source image may be shown using those sizes within the modified version of the source image, as discussed further with respect to other of the FIGS. 2C-2L. In this example embodiment, the BIMM system obtains 3D size information 260a1 for the dresser 255a1 that includes a width, length and height, and similarly obtains 3D size information 260a2 for the bedframe 255a2—in this example, the size information for the bedframe includes a width, a length, and multiple height sizes corresponding to different portions of the bedframe, such as a height to the top of the footboard, a height to the top of the headboard, and a height on the ground to the bottom of the bedframe's platform. While such target object sizes may be determined in various manners in various embodiments, as discussed in greater detail elsewhere herein, in this example the size information may be obtained from the same user (not shown) who indicated the source image to be modified and the target objects to be added, such as in response to a query to the user from the BIMM system. In addition, in this example the BIMM system has used information about the room visible in the source image from the associated building floor plan to associate sizes of dimensions of visible structural elements of the room, as shown with information overlaid in a version 250b of the source image, including a wireframe outline of the borders between walls, the floor and the ceiling, as well as an outline of the window structural element, with associated known sizes of those structural elements being shown on the modified version of the source image for the benefit of the reader. As discussed in greater detail elsewhere herein, the dimension information from the floor plan may be used to determine image-specific dimensions associated with the visual data of the source image, such as a number of pixel columns that correspond to a horizontal length of 8 feet along the exterior wall in the area of the window, differing numbers of pixel rows that correspond to the vertical length of 9 feet along the two sides of the exterior wall at corresponding areas of the source image, etc. In this example, the modified source image with the overlaid structural element information is provided for the benefit of the reader but may not be directly used by the BIMM system other than in the determination of image-specific dimension information for the included visual data, although in other embodiments the BIMM system may provide such a modified image with at least some of the overlaid information as conditioning information to a trained diffusion model (e.g., with the overlaid wireframe for the structural elements but without the shown dimensional information), as discussed in greater detail elsewhere herein.

FIGS. 2C and 2D continue the examples of FIGS. 2A-2B, and illustrates additional information 210c and 210d, respectively, in which the 3D dimensions of the bedframe have been used to determine a corresponding group of pixels 265c with a size and shape within the source image corresponding to the actual size of the bedframe (based on the position within the source image in which the group of pixels is illustrated), as shown with the group of pixels overlaid on a version 250c of the source image in FIG. 2C—the actual sizes of the bedframe used for the group of pixels 265c are illustrated for the benefit of the reader, and in this example correspond to a 3D geometrical shape (a rectangular prism cuboid) corresponding to the bedframe without the headboard—in other embodiments and situations, other sizes and shapes of the group of pixels may be used, as discussed further with respect to FIGS. 2E and 2F. In this example, the group of pixels may be overlaid on the source image and displayed to the user (not shown) in a GUI (not shown), with the user able to manipulate the group of pixels to move it in three dimensions 270c (or alternatively in two dimensions, such as to move it along the floor but not to raise it above the floor), but to not manually resize the group of pixels since it is constructed to correspond to the actual 3D size of the target object to be added. In this example, it will be appreciated that the group of pixels is further determined and displayed using an orientation that corresponds to the orientation of structural elements visible in the source image, such as the floor and walls, and if so the ability of the user to manipulate the orientation may be restricted (e.g., to allow the bedframe to be rotated along the floor along the yaw access but not rotated along the roll axis or the pitch axis), while in other embodiments such orientation information may not modifiable by the user or may not be used at all (e.g., with the bottoms and tops of the group of pixels being horizontal parallel to the bottom and top of the source image, rather than based on orientations of visual structural elements). FIG. 2D further illustrates the group of pixels after the user has moved it to a position that corresponds to the existing location of the bed visible in the source image, with the additional portions of the larger target object bedframe continuing outside the frame of the source image, as shown in a modified version 250d of the source image. As discussed in greater detail elsewhere herein, the actual size of the group of pixels may change as the group of pixels is moved to different positions of the source image, but with the group of pixels continuing to represent the same 3D size of the respective target object for the portion of the visual data of the source image that is visible at the position of the group of pixels.

FIGS. 2E and 2F continue the examples of FIGS. 2A-2D, and illustrate additional information 210e and 210f, respectively, to show alternative examples of the group of pixels used to represent the bedframe target object. In particular, FIG. 2E illustrates a modified shape 265e of the group of pixels that consists of a combination of two geometrical shapes, with the previous rectangular prism of FIGS. 2C-2D and a new rectangle or rectangular prism shape representing the headboard of the bedframe, as shown in the modified version 250e of the source image. Similarly, FIG. 2F illustrates a modified shape 265f of the group of pixels in which an outline of the bedframe is used instead of a solid 3D geometrical shape, such as formed by determining the bedframe outline shape from image 255a2 before performing rotation and sizing to correspond to the size and orientation of the group of pixels 265f in the modified version 250f of the source image.

FIG. 2G continues the examples of FIGS. 2A-2F, and illustrates additional information 210g showing a modified version 250g of the source image in which the group of pixels 265f for the bedframe target object has been positioned as shown, and in which an additional group of pixels 266g for the bedroom dresser has similarly been generated with a determined size and shape corresponding to that of the dresser target object and positioned as shown. In other embodiments, only a single target object may be added to a source image at a time. As in FIG. 2C, the dimensions of the dresser target object are illustrated for the sake of the reader, but may not be included in the conditioning information (e.g., conditional control images) that are generated and used in the generation of the modified source image, as discussed further with respect to FIGS. 2H-2I.

FIGS. 2H and 2I continue the examples of FIGS. 2A-2G, and illustrate information 210h and 210i, respectively, to show how the generated and positioned pixel groups of FIG. 2G may be further used to generate conditioning information used in generating a modified version of the source image that shows the two target objects to be added. In particular, in this example, FIG. 2H shows an additional image 250h that is generated as conditioning information, including in this example to generate an image with the same size and shape is that of the source image and to include binary pixel masks 265h and 266h for the bedframe and dresser target objects, respectively, with the binary pixel masks positioned according to the positioning of the groups of pixels 265f and 266g of FIG. 2G overlaid on the source image, and with the remainder of the image 250h having the opposite pixel value of the binary pixel masks (e.g., using a value of one, or black, for the pixel mass, and the opposite value of zero, or white, for the remainder of the image). In other embodiments and situations, the conditional control image or other conditioning information with the pixel masks may be overlaid on the source image, such as to obscure or block corresponding original pixels of the source image while the other original pixels of the source image remain visible.

FIG. 2I further illustrates a modified version 250h′ of the image 250h, which is input as conditioning information to one or more trained machine learning diffusion models 144, along with the source image 250a, and the images 255a1 and 255a2 of the target objects to be added—if multiple target objects are added in the manner of the current example, the multiple pixel masks of the image 250h′ may be associated with the respective target object in various manners, including using metadata associated with the image 250h′, or instead the multiple target objects may be successively added to the source image and subsequent modified versions of the source image that include one or more previously added target objects. In this example, the modification to the image 250h includes adding additional partial pixel mask 267i, which corresponds to areas of the source image around the pixel mask in which the trained diffusion model(s) 144 is to add additional shading as appropriate corresponding to the presence of the added bedframe in light of the illumination source (in this example, from the window in the external wall), such as may be automatically determined by the BIMM system via the identification of the window from analysis of the visual data of the source image and/or corresponding structural element information obtained from the floor plan, or instead without explicitly identifying illumination source(s) (e.g., to instead use different illumination levels for pixels in different portions of the source image) —as discussed in greater detail elsewhere, such partial pixel masks may use values between zero and one, while in other embodiments they may not be used. In this example, the trained diffusion model(s) 144 use various input information to generate a modified version 250i of the source image, in which the existing bed has been replaced with a new added bed using the bedframe target object, in which the empty space along the wall to the left of the source image has been replaced with a portion of the dresser target object, and in which the trained diffusion model(s) may optionally make other revisions to the source image, such as to adjust the size of the window, the flooring, the lighting, etc. in this example, although in other embodiments the portions of the source image outside the pixel mask may not be modified (e.g., to not modify the size and/or shape of the window(s) in the source image).

FIG. 2J continues the examples of FIGS. 2A-2I, and illustrates additional information 210j that includes a different source image 250j in which one or more target objects may be added to create a modified version of that source image. In particular, in this example the source image 250j is an exterior image of a building (e.g., the same house discussed with respect to the example floor plans of FIG. 1B), and in which a user (not shown) may have indicated to add one or more objects such as a front fence and/or a porch swing. In this example, respective pixel groups 268j (with separate portions 268j1 and 268j2) and 267j have been generated to correspond to actual sizes within the source image 250j of the respective front fence and porch swing target objects, and have been similarly positioned on the source image 250j (e.g., by manipulations of the user, by an automated positioning performed by the BIMM system, etc.)—while not illustrated here, similar conditioning information may be generated, including pixel masks (not shown) corresponding to the positions of the target objects to be added, and with a resulting modified version of the source image 250j (not shown) being generated to include the added objects.

FIG. 2K continues the examples of FIGS. 2A-2J, and illustrates additional information 210k that includes a different source image 250k1, and segmentation information 250k2 that is generated by the BIMM system to illustrate pixel masks 268k1 corresponding to existing objects identified in the source image 250i1, such as a desk and desk chair and desk lamp, a picture on the wall, an armchair, a rug, a couch, a window, a lighting fixture, etc. In some embodiments and situations, such segmentation information may optionally be further supplied to the trained diffusion model(s) as conditioning information (e.g., in addition to or instead of overlay information showing structural elements, such as that illustrated in FIG. 2B), such as to minimize changes made to portions of the source image in which a target object is not being added (e.g., by showing the segmentation information as Canny edges for object outlines instead of pixel masks as shown).

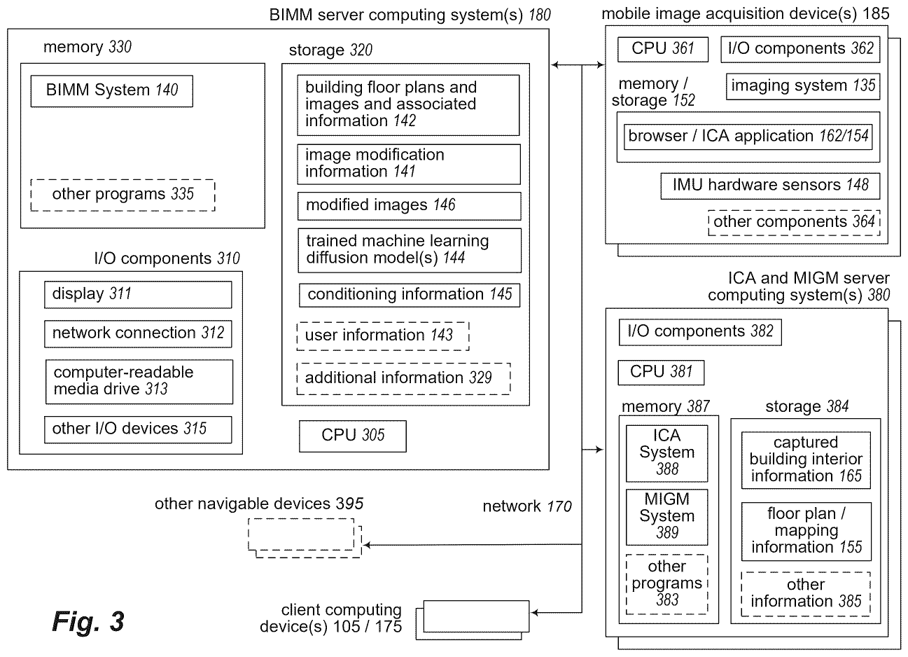

FIG. 2L continues the examples of FIGS. 2A-2K, and illustrates additional information 2101 that shows an example dataflow for operations of the BIMM system 140. In this example, the BIMM system 140 executes on one or more computing systems 180 (in a manner similar to that discussed further with respect to FIGS. 1A and 3), and may interact over one or more computer networks 170 with one or more client computing systems 105 and/or remote storage systems 181 (e.g., that store various information for a plurality of buildings, such as building images and floor plans). In this example, a user (not shown) of one of the client computing systems may interact with the BIMM system over the one or more computer networks to initiate the modification of a source image to include one or more indicated target objects, such as by selecting a source image that was captured at and associated with a particular building (not shown) and optionally provided to the client computing system for display (e.g., along with other building images and other building information for the building), and by further supplying information via a GUI (not shown) about modifications to make to the indicated source image-such modification information may include an image or other indication of a particular target object, size information for the target object, etc. In this example, the BIMM system in block 270 receives the image modification information 141, retrieves the source image (if not supplied by the user) and associated building floor plan (if available) 142 from storage (e.g., a database of building information), optionally stored locally on the computing systems 180 and/or remotely on one or more storage systems 181, and optionally further retrieves user information 143 specific to the user, such as to enable operations of the BIMM system to be personalized to the user in one or more manners. In block 282, a source image dimension determiner component of the BIMM system determines dimensions 271 of the visual data within the source image, such as by using the retrieved floor plan if available or by analyzing the visual data or other data associated with the source image. In block 283, an image-specific object visual representation generator component of the BIMM system then generates a visual representation 272 of the target object in a manner that is specific to the source image, such as to include a size, shape and optionally orientation based on the dimensions 271 determined for the source image. In block 284, an on-source-image object visual representation positioner component of the BIMM system then determines a position on the source image for a group of pixels corresponding to the visual representation 272, optionally via one or more interactions with the user, so as to determine contiguous pixel locations 273 within the source image corresponding to the positioned on-source-image object visual representation. In block 285, a conditional control image generator component of the BIMM system then generates one or more conditional control images 274 using the contiguous pixel locations 273, such as an image with the same shape and size as a source image with a pixel mask added over the contiguous pixel locations, and optionally with a partial pixel mask added over one or more additional adjacent or otherwise nearby pixel locations, and with the image optionally including only the pixel mask or instead being a copy of the source image with the pixel mask overlaid on it. Other conditioning information 274 may further include an image of the target object to be added (as supplied by the user), overlay information for the source image (whether on a modified version of the source image or other separate image) to show structural elements and/or positions of detected objects, etc. In block 286, a modified search image generator component of the BIMM system then interacts with one or more trained machine learning diffusion models 144 to generate a modified version of the source image 146 that includes the target object added at the locations of the position object visual representation, such as by supplying the conditional control images 274 and optionally additional information (e.g., the source image, such as if not already included in the conditional control images via overlay of pixel mask or other information on the source image; textual prompt instructions related to actions for the diffusion models to take; etc.). In block 289, the generated modified version of the source image 146 is then presented or otherwise provided to the user, such as by being transmitted over the one or more networks 170 to the client computing system 105 of the user for display.

Various details have been provided with respect to FIGS. 2A-2L, but it will be appreciated that the provided details are non-exclusive examples included for illustrative purposes, and other embodiments may be performed in other manners without some or all such details.

FIG. 1A includes an example block diagram of various computing devices and systems that may participate in the described techniques in some embodiments, such as with respect to an example building 198 (in this example, a house), and by the example Building Image Modification Manager (“BIMM”) system 140 executing on one or more server computing systems 180 in this example embodiment.

In the illustrated embodiment, information about the building 198 has been previously acquired, such as building images acquired at a variety of image acquisition locations 210A-210P, and a corresponding building floor plan has been generated, as discussed further with respect to FIG. 1B. In this example, an optional Image Capture and Analysis (ICA) system 160 may have participated in the prior capture and analysis of building images and other building information 165, such as to identify various objects and other structural elements of the building, and an optional Mapping Information Generation Manager (MIGM) system 160 may have participated in generating a building floor plan and optionally other building information 155 from analysis of the captured building images and other information 165. Additional details are included below regarding the operation of the ICA and MIGM systems in some embodiments.

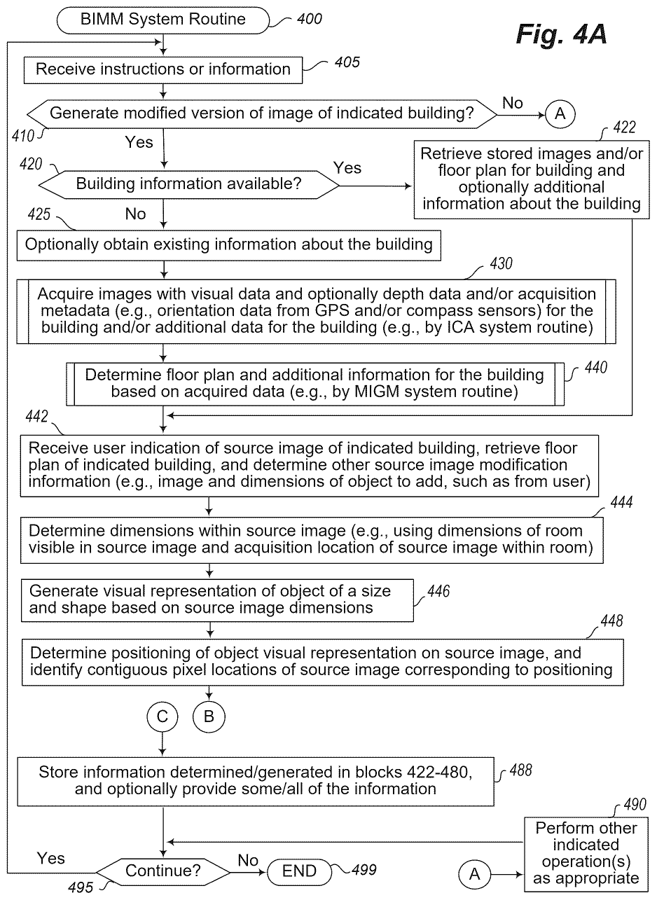

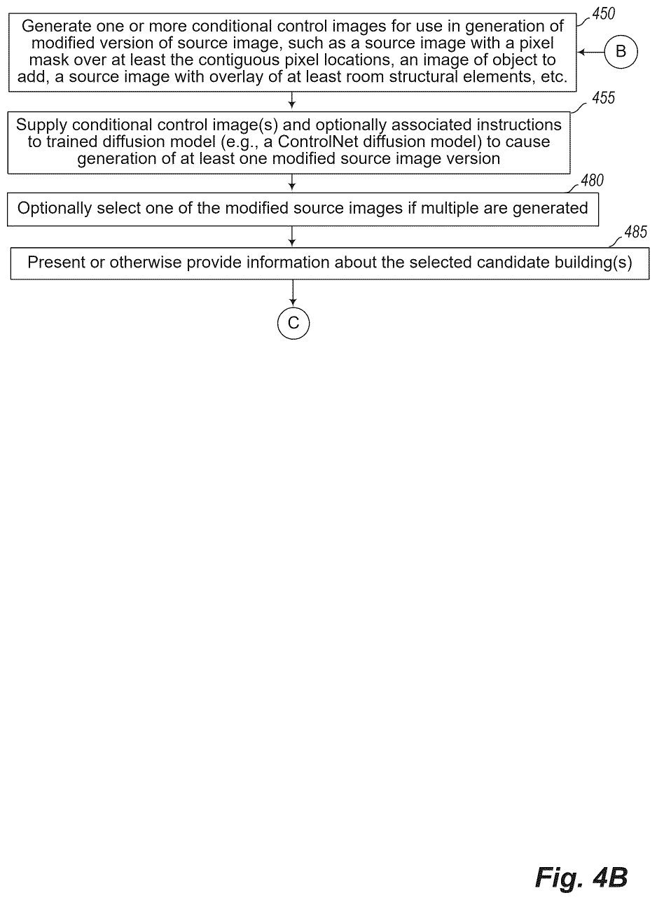

The BIMM system 140 In the illustrated embodiment uses previously acquired information about the building 198 in order to automatically modify a source image acquired at the building 198 to add a target object of a defined size by using image-specific dimensions of parts of the building visible in the source image and without using a three-dimensional object model of the target object. In at least some embodiments and situations, the source image to be modified is selected from building information 142 that is associated with building 198 (and optionally with many other buildings, not shown), such as with the building information 142 including captured building images and other building information 165, and the determination of dimensions of visible objects or other structural elements in the source image is based in part on a generated floor plan for building 198, such as with the building information 142 further including generated building floor plans and/or other mapping information 155. As part of doing so, the BIMM system may receive an indication of a source image to use (e.g., selected from multiple previously captured images of the building from building information 142), and analyze visual data of the source image to determine image-specific dimensions within the visual data of the source image (e.g., based at least in part on identified objects or other structural elements, and such as by using information from a floor plan of the building in building information 142 that includes dimensions of such objects or other structural elements). The BIMM system may further obtain image modification information in part or in whole from a user (not shown) of a client computing device 175 over intervening computer network(s) 170, such as an indication of a particular source image to use, information about a target object to add to a modified version of the source image (e.g., an image of the target object, actual 3D size of the target object, etc.), and information about where to position the target object within the modified version of the source image (e.g., by positioning a determined group of pixels with a size and shape corresponding the target object's actual 3D size as adjusted to match the image-specific dimensions of the source image's visual data). The BIMM system 140 may optionally obtain and use information 143 about the user (e.g., to personalize operations performed by the BIMM system), and may further use one or more trained diffusion models 144 to generate one or more modified versions 146 of the source image that include at least one added target object, such as by generating and supplying conditioning information 145 (e.g., the image of the target object; a conditional control image that is the same size and shape as the source image but with a pixel mask added to correspond to the determined position of the group of pixels representing the target object being added, with the conditional control image optionally being the source image with the pixel mask overlaid on it; etc.) as input to the diffusion model(s) along with a copy of the source image. A generated modified version of the image 146 may then be displayed to the user on the client computing device 175 and/or otherwise used in one or more automated manners. In some embodiments and situations, the BIMM system may optionally further use supporting information supplied by system operator users via computing devices 105 over intervening computer network(s) 170. In some embodiments, the building images and/or floor plans 142 that are used by the BIMM system may be obtained in manners other than via ICA and/or MIGM systems 160 (e.g., if such ICA and/or MIGM systems are not part of the BIMM system), such as to receive building images and/or floor plans from other sources (e.g., from the user). Additional details related to the automated operations of the BIMM system are included elsewhere herein, including with respect to FIGS. 2I-2L and FIGS. 4A-4B.

In addition, an ICA system may be used in some embodiments (e.g., an ICA system 160 executing on the one or more server computing systems 180, such as part of the BIMM system; an optional ICA system application 154 executing on a mobile image acquisition device 185; etc.) as part of capturing information 165 with respect to one or more buildings or other structures (e.g., by capturing one or more 360° panorama images and/or other images for multiple acquisition locations 210 in an example house 198), and a MIGM (Mapping Information Generation Manager) system 160 executing on the one or more server computing systems 180 (e.g., as part of the BIMM system) further uses that captured building information and optionally additional supporting information (e.g., supplied by system operator users via computing devices 105 over intervening computer network(s) 170) to generate and provide building floor plans 155 and/or other mapping-related information (not shown) for the building(s) or other structure(s). In the illustrated embodiment, the ICA and MIGM systems 160 are operating as part of the BIMM system 140 that uses building images 142 (e.g., images 165 acquired by the ICA system) and generates and uses corresponding building information 155 (e.g., as part of floor plan generation by the MIGM system) in one or more further automated manners, but in other embodiments may operate separately from the BIMM system. Similarly, while the ICA and MIGM systems 160 are illustrated in this example embodiment as executing on the same server computing system(s) 180 as the BIMM system (e.g., with all systems being operated by a single entity or otherwise being executed in coordination with each other, such as with some or all functionality of all the systems integrated together), in other embodiments the ICA system 160 and/or MIGM system 160 and/or BIMM system 140 may operate on one or more other systems separate from the system(s) 180 (e.g., on mobile device 185; on one or more other computing systems, not shown; etc.), whether instead of or in addition to the copies of those systems executing on the system(s) 180 (e.g., to have a copy of the MIGM system 160 executing on the device 185 to incrementally generate at least partial building floor plans as building images are acquired by the ICA system 160 executing on the device 185 and/or by that copy of the MIGM system, while another copy of the MIGM system optionally executes on one or more server computing systems to generate a final complete building floor plan after all images are acquired), and in yet other embodiments the BIMM may instead operate without an ICA system and/or MIGM system and instead obtain panorama images (or other images) and/or building floor plans from one or more external sources. Additional details related to the automated operation of the ICA and MIGM systems are included elsewhere herein.

Various components of the mobile computing device 185 are also illustrated in FIG. 1A, including one or more hardware processors 132 (e.g., CPUs, GPUS, etc.) that execute software (e.g., optional ICA application 154, optional browser 162, etc.) using executable instructions stored and/or loaded on one or more memory/storage components 152 of the device 185, and optionally one or more imaging systems 135 of one or more types to acquire visual data of one or more panorama images 165 and/or other images (not shown, such as rectilinear perspective images)—some or all such images may in some embodiments be supplied by one or more separate associated camera devices 184 (e.g., via a wired/cabled connection, via Bluetooth or other inter-device wireless communications, etc.), whether in addition to or instead of images captured by the mobile device 185. The illustrated embodiment of mobile device 185 further includes one or more sensor modules 148 that include a gyroscope 148a, accelerometer 148b and compass 148c in this example (e.g., as part of one or more IMU units, not shown separately, on the mobile device), one or more control systems 147 managing I/O (input/output) and/or communications and/or networking for the device 185 (e.g., to receive instructions from and present information to the user) such as for other device I/O and communication components 133 (e.g., network interfaces or other connections, keyboards, mice or other pointing devices, microphones, speakers, GPS receivers, etc.), a display system 149 (e.g., with a touch-sensitive screen), optionally one or more depth-sensing sensors or other distance-measuring components 136 of one or more types, optionally a GPS (or Global Positioning System) sensor 134 or other position determination sensor (not shown in this example), etc. Other computing devices/systems 105, 175 and 180 and/or camera devices 184 may include various hardware components and stored information in a manner analogous to mobile device 185, which are not shown in this example for the sake of brevity, and as discussed in greater detail below with respect to FIG. 3.

One or more users (not shown) of one or more client computing devices 175 may further interact over one or more computer networks 170 with the BIMM system 140 (and optionally the ICA system 160 and/or MIGM system 160), such as to request and participate in the generating of the modified images 146 and/or to receive and present the modified images 146, as well as obtaining and using the underlying images 165 and/or resulting floor plans 155 in one or more further automated manners—such interactions by the user(s) may include, for example, supplying image modification information 141, as well as specifying target criteria to use in searching for matching building or otherwise providing information about target criteria of interest to the users, or obtaining and optionally interacting with one or more particular groups of building information (e.g., to change between a floor plan view and a view of a particular image at an acquisition location within or near the floor plan; to change the horizontal and/or vertical viewing direction from which a corresponding view of a panorama image is displayed, such as to determine a portion of a panorama image to which a current user viewing direction is directed, etc.). Also, while not illustrated in FIG. 1A, in some embodiments the client computing devices 175 (or other devices, not shown) may receive and use information about modified images 146 and/or other building-related information in additional manners.

In the depicted computing environment of FIG. 1A, the network 170 may be one or more publicly accessible linked networks, possibly operated by various distinct parties, such as the Internet. In other implementations, the network 170 may have other forms. For example, the network 170 may instead be a private network, such as a corporate or university network that is wholly or partially inaccessible to non-privileged users. In still other implementations, the network 170 may include both private and public networks, with one or more of the private networks having access to and/or from one or more of the public networks. Furthermore, the network 170 may include various types of wired and/or wireless networks in various situations. In addition, the client computing devices 175 and server computing systems 180 may include various hardware components and stored information, as discussed in greater detail below with respect to FIG. 3, and the devices 175 may in some embodiments execute a building information access viewer system that provides a GUI with which a user of the device 175 interacts in order to obtain and view building information, including to supply image modification information 141 and to receive and display resulting modified images 146. One or more end users (not shown) of one or more building information access client computing devices 175 may further interact over computer networks 170 with the BIMM system 140 (and optionally the MIGM system 160 and/or ICA system 160), such as to obtain, display and interact with a generated floor plan (and/or other generated mapping information) and/or associated images (e.g., by supplying information about one or more indicated buildings of interest and/or other criteria and receiving information about one or more corresponding matching buildings), as discussed in greater detail elsewhere herein.

FIG. 1B continues the example of FIG. 1A and further illustrates information 110b including one example of a 2D floor plan 230b for the house 198, such as may be generated by a MIGM system and presented to an end-user in a GUI 260b, with the living room being the most westward room of the house (as reflected by directional indicator 209)—it will be appreciated that a 3D or 2.5D floor plan building model with rendered wall height information may be similarly generated and displayed in some embodiments, whether in addition to or instead of such a 2D floor plan, with one example of such a floor plan building model 265b further illustrated in FIG. 1B. Various types of information are illustrated on the 2D floor plan 230b in this example. For example, such types of information may include one or more of the following: room labels added to some or all rooms (e.g., “living room” for the living room); room dimensions added for some or all rooms, such as based on building dimension information determined by the MIGM system; visual indications of features such as installed fixtures or appliances (e.g., kitchen appliances, bathroom items, etc.) or other built-in elements (e.g., a kitchen island) added for some or all rooms; visual indications added for some or all rooms of positions of additional types of associated and linked information (e.g., of other panorama images and/or perspective images that an end-user may select for further display, of audio annotations and/or sound recordings that an end-user may select for further presentation, etc.); visual indications added for some or all rooms of structural features such as doors and windows; visual indications of visual appearance information (e.g., color and/or material type and/or texture for installed items such as floor coverings or wall coverings or surface coverings); visual indications of views from particular windows or other building locations and/or of other information external to the building (e.g., a type of an external space; items present in an external space; other associated buildings or structures, such as sheds, garages, pools, decks, patios, walkways, gardens, etc.); a key or legend 269 identifying visual indicators used for one or more types of information; etc. In the illustrated example, the room dimension information may include at least the widths of the walls, such as illustrated for the living room (e.g., 40 feet in the north-south direction, and 35 feet in the east-west direction), and may further in some embodiments and situations include additional dimensions, such as illustrated for the bedroom 2 room 197, such as at least widths of additional structural elements such as the windows (e.g., 8 feet), widths of other portions of the south wall on which the windows are located (e.g., 1 foot for the portion of the south wall to the east of the windows, and 3 feet for the portion of the south wall to the west of the windows)—while not illustrated in this example, room dimensions may further include dimensions of other objects (e.g., built-in structural elements, furniture, etc.) and/or dimensions other than width (e.g., heights, such as floor-to-ceiling for the walls; depths, such as the widths of the walls or 3D dimensions for objects and 3D structural elements; etc.). When displayed as part of a GUI, some or all such illustrated information may be user-selectable controls (or be associated with such controls) that allows an end-user to select and display some or all of the associated information (e.g., to select the 360° panorama image indicator for acquisition location 210B to view some or all of that panorama image; to select a perspective image indicator in room 197, not shown, to view some or all of that perspective image, such as in a manner similar to that of FIG. 2A; etc.). In addition, in this example a user-selectable control 228 is added to indicate a current story that is displayed for the floor plan, and to allow the end-user to select a different story to be displayed—in some embodiments, a change in stories or other levels may also be made directly from the floor plan, such as via selection of a corresponding connecting passage in the illustrated floor plan (e.g., the stairs to story 2), and other visual changes may be made directly from the displayed floor plan by selecting corresponding displayed user-selectable controls (e.g., to select a control corresponding to a particular image at a particular location, and to receive a display of that image, whether instead of or in addition to the previous display of the floor plan from which the image is selected). In other embodiments, information for some or all different floors may be displayed simultaneously, such as by displaying separate sub-floor plans for separate floors, or instead by integrating the room connection information for all rooms and floors into a single floor plan that is shown together at once.

Thus, a floor plan (or portion of it) may be linked to or otherwise associated with one or more additional types of information, such as one or more associated and linked images or other associated and linked information, including for a two-dimensional (“2D”) floor plan of a building to be linked to or otherwise associated with a separate 2.5D model floor plan rendering of the building and/or a 3D model floor plan rendering of the building, etc., and including for a floor plan of a multi-story or otherwise multi-level building to have multiple associated sub-floor plans for different stories or levels that are interlinked (e.g., via connecting stairway passages) or are part of a common 2.5D and/or 3D model. Accordingly, non-exclusive examples of an end user's interactions with a displayed or otherwise generated 2D floor plan of a building may include one or more of the following: to change between a floor plan view and a view of a particular image at an acquisition location within or near the floor plan; to change between a 2D floor plan view and a 2.5D or 3D model view that optionally includes images texture-mapped to walls of the displayed model; to change the horizontal and/or vertical viewing direction from which a corresponding subset view of (or portal into) a panorama image is displayed, such as to determine a portion of a panorama image in a 3D coordinate system to which a current user viewing direction is directed, and to render a corresponding planar image that illustrates that portion of the panorama image without the curvature or other distortions present in the original panorama image; etc.

FIG. 1B further illustrates additional information 265b that may be generated in the same manner as the floor plan 230b (e.g., by determining and associating wall height information with room wall dimensions) and displayed (e.g., in a GUI similar to that of floor plan 230 b), which in this example is a 2.5D or 3D model floor plan of the house. Such a model 265b may be additional mapping-related information that is generated based on the floor plan 230b, with additional information about height shown in order to illustrate visual locations in walls of structural element features such as windows and doors, or instead generated by combining final estimated room shapes that are 3D shapes and are determined by the MIGM system. While not illustrated in this example, various types of additional information may be determined for the building and added to the floor plan model 265b in some embodiments and situations, such as the types of information illustrated for floor place 230b. In addition, further information may be added to the displayed walls in some embodiments, such as from images taken during the video capture (e.g., to render and illustrate actual paint, wallpaper or other surfaces from the house on the rendered model 265), and/or may otherwise be used to add specified colors, textures or other visual information to walls and/or other surfaces.

It will be appreciated that a variety of other types of information may be added in some embodiments to the floor plans 230b and/or 265b, that some of the illustrated types of information may not be provided in some embodiments, and that visual indications of and user selections of linked and associated information may be displayed and selected in other manners in other embodiments. Additional details regarding a BIIP (Building Information Integrated Presentation) system and/or an ILTM (Image Locations Transition Manager) system, which are example embodiments of systems to provide or otherwise support at least some functionality of a building information access system and routine as discussed herein, are included in U.S. Non-Provisional Patent Application No. Ser. No. 16/681,787, filed Nov. 12, 2019 and entitled “Presenting Integrated Building Information Using Three-Dimensional Building Models,” and in U.S. Non-Provisional Patent application Ser. No. 15/950,881, filed Apr. 11, 2018 and entitled “Presenting Image Transition Sequences Between Acquisition Locations,” each of which is incorporated herein by reference in its entirety.

Returning back to FIG. 1A, the ICA system may in some embodiments perform automated operations involved in generating multiple 360° panorama images at multiple associated acquisition locations (e.g., in multiple rooms or other locations within a building or other structure and optionally around some or all of the exterior of the building or other structure), such as using visual data acquired via the mobile device(s) 185 and/or associated camera devices 184, and for use in generating and providing a representation of the building or other structure. For example, in at least some such embodiments, such techniques may include using one or more mobile devices (e.g., a camera having one or more fisheye lenses and mounted on a rotatable tripod or otherwise having an automated rotation mechanism, a camera having sufficient fisheye lenses to capture 360° horizontally without rotation, a smart phone held and moved by a user, a camera held by or mounted on a user or the user's clothing, etc.) to capture data from a sequence of multiple acquisition locations within multiple rooms of a house (or other building), and to optionally further capture data involved in movement of the acquisition device (e.g., movement at an acquisition location, such as rotation; movement between some or all of the acquisition locations, such as for use in linking the multiple acquisition locations together; etc.), in at least some cases without having distances between the acquisition locations being measured or having other measured depth information to objects in an environment around the acquisition locations (e.g., without using any depth-sensing sensors). After an acquisition location's information is captured, the techniques may include producing a 360° panorama image from that acquisition location with 360 degrees of horizontal information around a vertical axis (e.g., a 360° panorama image that shows the surrounding room in an equirectangular format, with straight vertical data such as the sides of a typical rectangular door frame or a typical border between 2 adjacent walls remaining straight, and with straight horizontal data such as the top of a typical rectangular door frame or a border between a wall and a floor remaining straight at a horizontal midline of the image but being increasingly curved in the equirectangular projection image in a convex manner relative to the horizontal midline as the distance increases in the image from the horizontal midline), and then providing the panorama images for subsequent use by the MIGM and/or BIMM systems. Additional details related to embodiments of a system providing at least some such functionality of an ICA system are included in U.S. Non-Provisional patent application Ser. No. 16/693,286, filed Nov. 23, 2019 and entitled “Connecting And Using Building Data Acquired From Mobile Devices” (which includes disclosure of an example BICA system that is generally directed to obtaining and using panorama images from within one or more buildings or other structures); in U.S. Non-Provisional patent application Ser. No. 16/236,187, filed Dec. 28, 2018 and entitled “Automated Control Of Image Acquisition Via Use Of Acquisition Device Sensors” (which includes disclosure of an example ICA system that is generally directed to obtaining and using panorama images from within one or more buildings or other structures); and in U.S. Non-Provisional patent application Ser. No. 16/190,162, filed Nov. 14, 2018 and entitled “Automated Mapping Information Generation From Inter-Connected Images”; each of which is incorporated herein by reference in its entirety. Additional details related to embodiments of a system providing at least some such functionality of an MIGM system or related system for generating floor plans and associated information and/or presenting floor plans and associated information are included in co-pending U.S. Non-Provisional patent application Ser. No. 16/190,162, filed Nov. 14, 2018 and entitled “Automated Mapping Information Generation From Inter-Connected Images” (which includes disclosure of an example Floor Map Generation Manager, or FMGM, system that is generally directed to automated operations for generating and displaying a floor map or other floor plan of a building using images acquired in and around the building); in U.S. Non-Provisional patent application Ser. No. 16/681,787, filed Nov. 12, 2019 and entitled “Presenting Integrated Building Information Using Three-Dimensional Building Models” (which includes disclosure of an example FMGM system that is generally directed to automated operations for displaying a floor map or other floor plan of a building and associated information); in U.S. Non-Provisional patent application Ser. No. 16/841,581, filed Apr. 6, 2020 and entitled “Providing Simulated Lighting Information For Three-Dimensional Building Models” (which includes disclosure of an example FMGM system that is generally directed to automated operations for displaying a floor map or other floor plan of a building and associated information); in U.S. Provisional Patent Application No. 62/927,032, filed Oct. 28, 2019 and entitled “Generating Floor Maps For Buildings From Automated Analysis Of Video Of The Buildings' Interiors” (which includes disclosure of an example Video-To-Floor Map, or VTFM, system that is generally directed to automated operations for generating a floor map or other floor plan of a building using video data acquired in and around the building); in U.S. Non-Provisional patent application Ser. No. 16/807,135, filed Mar. 2, 2020 and entitled “Automated Tools For Generating Mapping Information For Buildings” (which includes disclosure of an example MIGM system that is generally directed to automated operations for generating a floor map or other floor plan of a building using images acquired in and around the building); and in U.S. Non-Provisional patent application Ser. No. 17/013,323, filed Sep. 4, 2020 and entitled “Automated Analysis Of Image Contents To Determine The Acquisition Location Of The Image” (which includes disclosure of an example MIGM system that is generally directed to automated operations for generating a floor map or other floor plan of a building using images acquired in and around the building, and an example ILMM system for determining the acquisition location of an image on a floor plan based at least in part on an analysis of the image's contents); each of which is incorporated herein by reference in its entirety.

FIG. 1A further depicts an exemplary building interior environment in which 360° panorama images and/or other images are acquired, such as by the ICA system and for use by the MIGM system to generate and provide one or more corresponding building floor plans (e.g., multiple incremental partial building floor plans), as well as to later be used by the BIMM system as source images to be modified. In particular, FIG. 1A illustrates one story of a multi-story house (or other building) 198 with an interior that was captured at least in part via multiple panorama images, such as by a mobile image acquisition device 185 with image acquisition capabilities and/or one or more associated camera devices 184 as they are moved through the building interior to a sequence of multiple acquisition locations 210 (e.g., starting at acquisition location 210A, moving to acquisition location 210B along travel path 115, etc., and ending at acquisition location 210-O or 210P outside of the building). An embodiment of the ICA system may automatically perform or assist in the capturing of the data representing the building interior (as well as to further analyze the captured data to generate 360° panorama images to provide a visual representation of the building interior), and an embodiment of the MIGM system may analyze the visual data of the acquired images to generate one or more building floor plans for the house 198 (e.g., multiple incremental building floor plans, including to determine directions between images, such as directions 215-AB, 215-AC and 215-BC between image acquisition locations 210A, 210B and 210C). While such a mobile image acquisition device may include various hardware components, such as a camera, one or more sensors (e.g., a gyroscope, an accelerometer, a compass, etc., such as part of one or more IMUs, or inertial measurement units, of the mobile device; an altimeter; light detector; etc.), a GPS receiver, one or more hardware processors, memory, a display, a microphone, etc., the mobile device may not in at least some embodiments have access to or use equipment to measure the depth of objects in the building relative to a location of the mobile device, such that relationships between different panorama images and their acquisition locations in such embodiments may be determined in part or in whole based on features in different images but without using any data from any such depth sensors, while in other embodiments such depth data may be obtained and used. In addition, while directional indicator 109 is provided in FIG. 1A relative to the example house 198 for reference of the reader, the mobile device and/or ICA system may not use such absolute directional information and/or absolute locations in at least some embodiments, such as to instead determine relative directions and distances between acquisition locations 210 without regard to actual geographical positions or directions in such embodiments, while in other embodiments such absolute directional information and/or absolute locations may be obtained and used.

In operation, the mobile device 185 and/or camera device(s) 184 arrive at a first acquisition location 210A within a first room of the building interior (in this example, in a living room accessible via an external door 190-1), and captures or acquires a view of a portion of the building interior that is visible from that acquisition location 210A (e.g., some or all of the first room, and optionally small portions of one or more other adjacent or nearby rooms, such as through doorway wall openings, non-doorway wall openings, hallways, stairways or other connecting passages from the first room). The view capture may be performed in various manners as discussed herein, and may include a number of objects or other features (e.g., structural details) that may be visible in images captured from the acquisition location-in the example of FIG. 1A, such objects or other features within the building 198 include the doorways 190 (including 190-1 through 190-6, such as with swinging and/or sliding doors), windows 196 (including 196-1 through 196-8), corners or edges 195 (including corner 195-1 in the northwest corner of the building 198, corner 195-2 in the northeast corner of the first room, corner 195-3 in the southwest corner of the first room, corner 195-4 in the southeast corner of the first room, corner 195-5 at the northern edge of the inter-room passage between the first room and a hallway, etc.), furniture 191-193 (e.g., a couch 191; chair 192; table 193; etc.), pictures or paintings or televisions or other hanging objects 194 (such as 194-1 and 194-2) hung on walls, light fixtures (not shown in FIG. 1A), various built-in appliances or fixtures or other structural elements (not shown in FIG. 1A), etc. The user may also optionally provide a textual or auditory identifier to be associated with an acquisition location and/or a surrounding room, such as “living room” for one of acquisition locations 210A or 210B or for the room including acquisition locations 210A and/or 210B, while in other embodiments the ICA and/or MIGM system may automatically generate such identifiers (e.g., by automatically analyzing images and/or video and/or other recorded information for a building to perform a corresponding automated determination, such as by using machine learning; based at least in part on input from ICA and/or MIGM system operator users; etc.) or the identifiers may not be used.

After the first acquisition location 210A has been captured, the mobile device 185 and/or camera device(s) 184 may move or be moved to a next acquisition location (such as acquisition location 210B), optionally recording images and/or video and/or other data from the hardware components (e.g., from one or more IMUs, from the camera, etc.) during movement between the acquisition locations. At the next acquisition location, the mobile 185 and/or camera device(s) 184 may similarly capture a 360° panorama image and/or other type of image from that acquisition location. This process may repeat for some or all rooms of the building and in some cases external to the building, as illustrated for additional acquisition locations 210C-210P in this example (including acquisition location 210D in room 197 that includes a perspective image with an angle of view 199), with the images from acquisition locations 210A to 210-O being captured in a single image acquisition session in this example (e.g., in a substantially continuous manner, such as within a total of 5 minutes or 15 minutes), and with the image from acquisition location 210P optionally being acquired at a different time (e.g., from a street adjacent to the building or front yard of the building). In this example, multiple of the acquisition locations 210K-210P are external to but associated with the building 198, including acquisition locations 210L and 210M in one or more additional structures 189 on the same property 241 (e.g., an ADU, or accessory dwelling unit; a garage; a shed; etc., such as with an additional doorway 190-7, window 196-9, etc.), acquisition location 210K on an external deck or patio 186, and acquisition locations 210N-210P at multiple yard locations on the property (e.g., backyard 187, side yard 188, front yard including acquisition location 210P, etc.). Movements of the mobile device 185 and/or camera device 184 may occur through doorways 190 and non-doorway wall openings 263 (e.g., opening 263a between the living room and hallway, opening 263b between the hallway and the kitchen/dining room, opening 263c between the kitchen/dining room and family room, etc.). The acquired images for each acquisition location may be further analyzed, including in some embodiments to render or otherwise place each panorama image in an equirectangular format, whether at the time of image acquisition or later, as well as further analyzed by the MIGM and/or BIMM systems in the manners described herein.

In addition, in at least some embodiments and situations, some or all of the images acquired for a building and associated with the building's floor plan may be panorama images that are each acquired at one of multiple acquisition locations in or around the building, such as to generate a panorama image at each such acquisition location from one or more of a video at that acquisition location (e.g., a 360° video taken from a smartphone or other mobile device held by a user turning at that acquisition location), or multiple images acquired in multiple directions from the acquisition location (e.g., from a smartphone or other mobile device held by a user turning at that acquisition location), or a simultaneous capture of all the image information (e.g., using one or more fisheye lenses), etc. Such images may include visual data, and in at least some embodiments and situations, acquisition metadata regarding the acquisition of such panorama images may be obtained and used in various manners, such as data acquired from IMU (inertial measurement unit) sensors or other sensors of a mobile device as it is carried by a user or otherwise moved between acquisition locations (e.g., compass heading data, GPS location data, etc.). It will be appreciated that such a panorama image may in some situations be represented in an equirectangular coordinate system and provide up to 360° coverage around horizontal and/or vertical axes, such that a user viewing a starting panorama image may move the viewing direction within the starting panorama image to different orientations to cause different images (or “views”) to be rendered within the starting panorama image (including, if the panorama image is represented in a equirectangular coordinate system, to convert the image being rendered into a planar coordinate system).

Various details are provided with respect to FIGS. 1A and 1B, but it will be appreciated that the provided details are non-exclusive examples included for illustrative purposes, and other embodiments may be performed in other manners without some or all such details.

FIG. 3 is a block diagram illustrating an embodiment of one or more server computing systems 180 executing an implementation of a BIMM system 140, and one or more server computing systems 380 executing an implementation of an ICA system 388 and an MIGM system 389—the server computing system(s) and BIMM and/or ICA and/or MIGM systems may be implemented using a plurality of hardware components that form electronic circuits suitable for and configured to, when in combined operation, perform at least some of the techniques described herein. One or more computing systems and devices may also optionally be executing a Building Information Access system, not shown (such as server computing system(s) 180, client computing device(s) 175, etc.) and/or optional other programs 335 and 383 (such as server computing system(s) 180 and 380, respectively, in this example). In the illustrated embodiment, each server computing system 180 includes one or more hardware central processing units (“CPUs”) or other hardware processors 305, various input/output (“I/O”) components 310, storage 320, and memory 330, with the illustrated I/O components including a display 311, a network connection 312, a computer-readable media drive 313, and other I/O devices 315 (e.g., keyboards, mice or other pointing devices, microphones, speakers, GPS receivers, etc.). Each server computing system 380 may have similar components, although only one or more hardware processors 381, memory 387, storage 384 and I/O components 382 are illustrated in this example for the sake of brevity.

In the illustrated embodiment, the BIMM system 140 executes in memory 330 of the server computing system(s) 180 in order to perform at least some of the described techniques, such as by using the processor(s) 305 to execute software instructions of the system 140 in a manner that configures the processor(s) 305 and computing system 180 to perform automated operations that implement those described techniques. The illustrated embodiment of the BIMM system may include one or more components, not shown, to each perform portions of the functionality of the BIMM system, such as in a manner discussed elsewhere herein, and the memory may further optionally execute one or more other programs 335—as one specific example, a copy of the ICA and/or MIGM systems may execute as one of the other programs 335 in at least some embodiments, such as instead of or in addition to the ICA and/or MIGM systems 388-389 on the server computing system(s) 380, and/or a copy of a Building Information Access system may execute as one of the other programs 335. The BIMM system 140 may further, during its operation, store and/or retrieve various types of data on storage 320 (e.g., in one or more databases or other data structures), such as building information 142 including captured building images and building floor plans and optionally other building information (e.g., from information 155 and 165), image modification information 141 (e.g., images of target objects to added to source images, actual 3D sizes of target objects, positioning information for target objects within source images, etc.), one or more trained diffusion models 144, conditioning information 145 (e.g., conditional control images, images of target objects, etc.) to supply to the trained diffusion model(s) to cause the generation of modified images 146, optionally user information 143 related to users who interact with the BIMM system 140, and optionally additional information 329.

In addition, embodiments of the ICA and MIGM systems 388-389 execute in memory 387 of the server computing system(s) 380 in the illustrated embodiment in order to perform techniques related to capturing images and generating panorama images and floor plans for buildings, such as by using the processor(s) 381 to execute software instructions of the systems 388 and/or 389 in a manner that configures the processor(s) 381 and computing system(s) 380 to perform automated operations that implement those techniques. The illustrated embodiment of the ICA and MIGM systems may include one or more components, not shown, to each perform portions of the functionality of the ICA and MIGM systems, respectively, and the memory may further optionally execute one or more other programs 383. The ICA and/or MIGM systems 388-389 may further, during operation, store and/or retrieve various types of data on storage 384 (e.g., in one or more databases or other data structures), such as video and/or image information 165 acquired for one or more buildings (e.g., 360° video or images for analysis to generate floor plans, to provide to users of client computing devices 105/175 for display, etc.), floor plans and/or other generated mapping information 155, and optionally other information 385 (e.g., additional images and/or annotation information for use with associated floor plans, building and room dimensions for use with associated floor plans, various analytical information related to presentation or other use of one or more building interiors or other environments, etc.)—while not illustrated in FIG. 3, the ICA and/or MIGM systems may further store and use additional types of information, such as about other types of building information to be analyzed and/or provided to the BIMM system, about ICA and/or MIGM system operator users and/or end-users, etc.

The server computing system(s) 180 and executing BIMM system 140, server computing system(s) 380 and executing ICA and MIGM systems 388-389, and optionally executing Building Information Access system (not shown), may communicate with each other and with other computing systems and devices in this illustrated embodiment, such as via one or more networks 170 (e.g., the Internet, one or more cellular telephone networks, etc.), including to interact with end-user client computing devices 175 (e.g., used to view floor plans, and optionally associated images and/or other related information, such as by interacting with or executing a copy of the Building Information Access system), system user client computing devices 105 (e.g., used to configure and assist in operation of the BIMM system 140), and/or mobile image acquisition devices 185 (e.g., used to acquire images and/or other information for buildings or other environments to be modeled), and/or optionally other navigable devices 395 that receive and use floor plans and optionally other generated information for navigation purposes (e.g., for use by semi-autonomous or fully autonomous vehicles or other devices). In other embodiments, some of the described functionality may be combined in less computing systems, such as to combine the BIMM system 140 and a Building Information Access system in a single system or device, to combine the BIMM system 140 and the image acquisition functionality of device(s) 185 in a single system or device, to combine the ICA and MIGM systems 388-389 and the image acquisition functionality of device(s) 185 in a single system or device, to combine the BIMM system 140 and the ICA and MIGM systems 388-389 in a single system or device, to combine the BIMM system 140 and the ICA and MIGM systems 388-389 and the image acquisition functionality of device(s) 185 in a single system or device, etc.

Some or all of the user client computing devices 105/175 (e.g., mobile devices), mobile image acquisition devices 185, optional other navigable devices 395 and other computing systems (not shown) may similarly include some or all of the same types of components illustrated for server computing system 180. As one non-limiting example, the mobile image acquisition devices 185 are each shown to include one or more hardware CPU(s) 361, I/O components 362, memory and/or storage 152, one or more imaging systems 135, IMU hardware sensors 148 (e.g., for use in acquisition of video and/or images, associated device movement data, etc.), and optionally other components 364. In the illustrated example, one or both of a browser and one or more client applications 162/154 (e.g., an application specific to the BIMM system and/or to ICA system and/or to the MIGM system) are executing in memory 152, such as to participate in communication with the BIMM system 140, ICA system 388, MIGM system 389 and/or other computing systems. While particular components are not illustrated for the other navigable devices 395 or other computing devices/systems 105/175, it will be appreciated that they may include similar and/or additional components.

It will also be appreciated that computing systems 180 and 380 and the other systems and devices included within FIG. 3 are merely illustrative and are not intended to limit the scope of the present invention. The systems and/or devices may instead each include multiple interacting computing systems or devices, and may be connected to other devices that are not specifically illustrated, including via Bluetooth communication or other direct communication, through one or more networks such as the Internet, via the Web, or via one or more private networks (e.g., mobile communication networks, etc.). More generally, a device or other computing system may comprise any combination of hardware that may interact and perform the described types of functionality, optionally when programmed or otherwise configured with particular software instructions and/or data structures, including without limitation desktop or other computers (e.g., tablets, slates, etc.), database servers, network storage devices and other network devices, smart phones and other cell phones, consumer electronics, wearable devices, digital music player devices, handheld gaming devices, PDAs, wireless phones, Internet appliances, and various other consumer products that include appropriate communication capabilities. In addition, the functionality provided by the illustrated BIMM system 140 may in some embodiments be distributed in various components, some of the described functionality of the BIMM system 140 may not be provided, and/or other additional functionality may be provided.

It will also be appreciated that, while various items are illustrated as being stored in memory or on storage while being used, these items or portions of them may be transferred between memory and other storage devices for purposes of memory management and data integrity. Alternatively, in other embodiments some or all of the software components and/or systems may execute in memory on another device and communicate with the illustrated computing systems via inter-computer communication. Thus, in some embodiments, some or all of the described techniques may be performed by hardware means that include one or more processors and/or memory and/or storage when configured by one or more software programs (e.g., by the BIMM system 140 executing on server computing systems 180, by a Building Information Access system executing on server computing systems 180 or computing devices 175 or other computing systems/devices, etc.) and/or data structures, such as by execution of software instructions of the one or more software programs and/or by storage of such software instructions and/or data structures, and such as to perform algorithms as described in the flow charts and other disclosure herein. Furthermore, in some embodiments, some or all of the systems and/or components may be implemented or provided in other manners, such as by consisting of one or more means that are implemented partially or fully in firmware and/or hardware (e.g., rather than as a means implemented in whole or in part by software instructions that configure a particular CPU or other processor), including, but not limited to, one or more application-specific integrated circuits (ASICs), standard integrated circuits, controllers (e.g., by executing appropriate instructions, and including microcontrollers and/or embedded controllers), field-programmable gate arrays (FPGAs), complex programmable logic devices (CPLDs), etc. Some or all of the components, systems and data structures may also be stored (e.g., as software instructions or structured data) on a non-transitory computer-readable storage mediums, such as a hard disk or flash drive or other non-volatile storage device, volatile or non-volatile memory (e.g., RAM or flash RAM), a network storage device, or a portable media article (e.g., a DVD disk, a CD disk, an optical disk, a flash memory device, etc.) to be read by an appropriate drive or via an appropriate connection. The systems, components and data structures may also in some embodiments be transmitted via generated data signals (e.g., as part of a carrier wave or other analog or digital propagated signal) on a variety of computer-readable transmission mediums, including wireless-based and wired/cable-based mediums, and may take a variety of forms (e.g., as part of a single or multiplexed analog signal, or as multiple discrete digital packets or frames). Such computer program products may also take other forms in other embodiments. Accordingly, embodiments of the present disclosure may be practiced with other computer system configurations.

FIGS. 4A-4B illustrate an example flow diagram of an embodiment of a BIMM system routine 400. The routine may be performed as a computer-implemented method by, for example, the BIMM system 140 of FIG. 1A, the BIMM system 140 of FIG. 3, and/or a BIMM system as described with respect to FIGS. 2A-2L and elsewhere herein, such as to automatically modify a source image acquired at a building to add a target object of a defined size by using image-specific dimensions of parts of the building visible in the source image and without using a three-dimensional object model of the target object.

The illustrated embodiment of the routine begins at block 405, where instructions or other information is received. In block 410, the routine then determines whether the instructions or other information received in block 405 indicate to generate a modified version of the source image of an indicated building, and if not the routine continues to block 490. Otherwise, the routine continues to perform blocks 420-488. In particular, in block 420, the routine determines whether one or more source images and other information about the indicated building is already available, and if so continues to block 422 to retrieve the stored images and optionally other information for the building (e.g., a floor plan of the building). Otherwise, the routine continues to block 425 to optionally obtain existing information about the building (e.g., associated location information), and in block 430 acquires images with visual data and optionally depth data for the indicated building, optionally along with further acquisition metadata (e.g., orientation and/or location data from GPS and/or compass and/or IMU sensors), such as in at least some embodiments by use of an ICA system as discussed in greater detail elsewhere herein. In block 440, the routine then uses the data acquired in block 430 to determine a floor plan and optionally additional mapping information for the building, such as in at least some embodiments by use of an MIGM system as discussed in greater detail elsewhere herein.

After blocks 422 or 440, the routine continues to block 442 to receive an indication from an end user of the source image of the indicated building, and to retrieve the floor plan of the indicated building, and to further determine other modification information for the source image (e.g., an image and actual 3D size dimensions of the target object at the source image, such as from the end user) in at least some embodiments and situations, the indication of the source image include selection by the end-user of one of the previously acquired images for the indicated building, such as from blocks 422 or 430. In block 444, the routine then determines dimensions of visual data within the source image, such as using objects or other structural elements visible in a room shown in the source image and information about an acquisition location of the source image within the room, such as by using information from the retreat floor plan of the indicated building. In block 446, the routine then generates a visual representation of the target object using a group of pixels having a size and shape based on the actual size and shape of the target object within the dimensions of the visual data of the source image. In block 448, the routine then determines positioning of the object visual representation on the source image, such as in at least some embodiments based on input from the end user to position the visual representation of the group of pixels, and to identify contiguous pixel locations of the source image corresponding to the positioning (e.g., those pixels of the source image covered by the positioned visual representation).

After block 448, the routine continues to block 450 to generate one or more conditional control images for use in generation of the modified version of the source image, such as an image of the target object to add, an image with the size and shape of the source image and having a pixel mask over at least the contiguous pixel locations that is optionally further extended to include additional pixel locations with a partial pixel mask that represent pixels of the source image on which to add shading corresponding to one or more illumination sources in the source image (e.g., a version of the source image with the pixel mask and optionally the partial pixel mask overlaid, a blank image with the pixel mask and optionally the partial pixel mask overlaid, etc.), optionally an image with the size and shape of the source image and having information overlaid to indicate structural elements of one or more rooms visible in the source image (e.g., a version of the source image with the structural element information overlaid, a blank image with the structural element information overlaid, etc.), etc. In block 455, the routine then supplies the one or more conditional control images and optionally additional information (e.g., a copy of the source image, textual prompt instructions, etc.) to the trained diffusion model (e.g., a ControlNet architecture diffusion model) to cause generation of at least one modified version of the source image. In block 480, the routine then optionally selects one of the multiple modified source images if multiple are generated, and in block 485, presents or other otherwise provides information about the selected modified source image (or the single generated modified source image if only one is generated). After block 485, the routine continues to block 488, where it stores information determined and/are generated in blocks 422-480.

In block 490, the routine optionally performs one or more other indicated operations from block 405 as appropriate, with non-exclusive examples including receiving and storing information about users, receiving and responding to requests for previously generated modified source images and/or other previously generated information, receiving and storing building images and/or building floor plans from sources other than block 430 and 440 (e.g., external sources outside the BIMM system), etc.

Following blocks 480 or 490, the routine proceeds to block 495 to determine whether to continue, such as until an explicit indication to terminate is received, or instead only if an explicit indication to continue is received. If it is determined to continue, the routine returns to block 405 to await additional instructions or information, and if not proceeds to step 499 and ends.

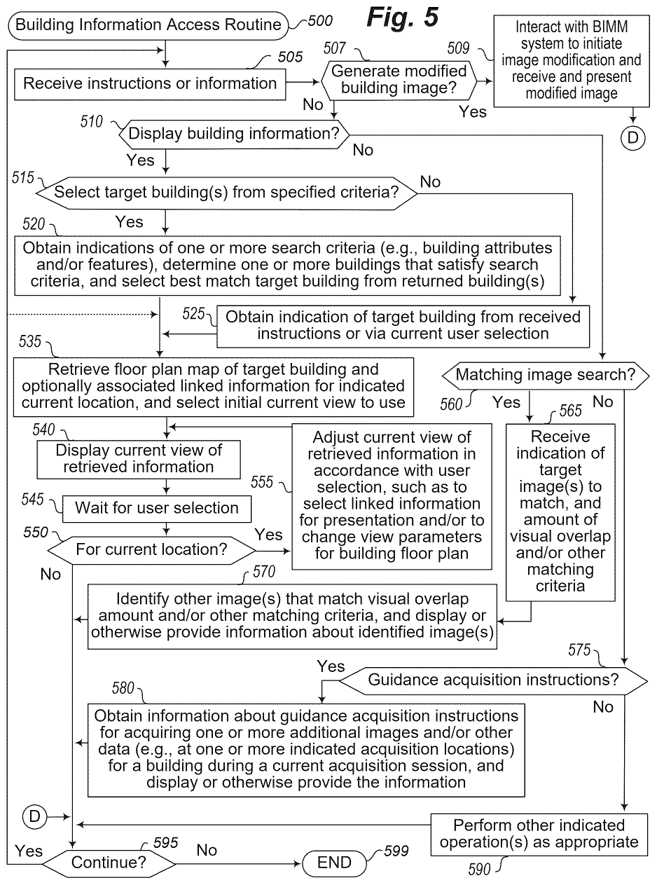

FIG. 5 illustrates an example embodiment of a flow diagram for a Building Information Access system routine 500. The routine may be performed as a computer-implemented method by, for example, execution of a building information access client computing device 175 and its software system(s) (not shown) of FIG. 1A, a client computing device 105/175 of FIG. 3, and/or a building information access viewer or presentation system as described elsewhere herein, such as to receive and display generated floor plans and/or other mapping information (e.g., determined room structural layouts/shapes, etc.) for a defined area that optionally include visual indications of one or more determined image acquisition locations, to obtain and display information about images matching one or more indicated target images, to display additional information (e.g., images) associated with particular acquisition locations in the mapping information, to obtain and display guidance acquisition instructions provided by the BIMM system and/or other sources (e.g., with respect to other images acquired during that acquisition session and/or for an associated building, such as part of a displayed GUI), to obtain and display explanations or other descriptions of matching between two or more buildings or properties, etc. In the example of FIG. 5, the presented mapping information is for a building (such as an interior of a house), but in other embodiments, other types of mapping information may be presented for other types of buildings or environments and used in other manners, as discussed elsewhere herein.

The illustrated embodiment of the routine begins at block 505, where instructions or information are received. At block 507, the routine determines whether the received instructions or information in block 505 are to generate a modified image of a building, and if so the routine continues to block 507 to interact with the BIMM system to initiate and direct the generation of the modified image, and to receive and present the modified image-such interactions with the BIMM system may include having the user select or otherwise indicate a source image that is associated with a particular building and is to be modified (e.g., by selecting one of multiple building images that are previously associated with and provided with information about the indicated building), having the user supply information about a target object to be added to a modified version of the source image (e.g., an image of the object, actual 3D size of the object, etc.), indicating where the object should be positioned within the source image (e.g., by positioning a group of pixels that represent the size and shape of the object within the image), etc. Otherwise, the routine at block 510 determines whether the received instructions or information in block 505 are to display determined information for one or more target buildings, and if so continues to block 515 to determine whether the received instructions or information in block 505 are to select one or more target buildings using specified criteria (e.g., based at least in part on an indicated building), and if not continues to block 525 to obtain an indication of a target building to use from the user (e.g., based on a current user selection, such as from a displayed list or other user selection mechanism; based on information received in block 505; etc.). Otherwise, if it is determined in block 515 to select one or more target buildings from specified criteria (e.g., based at least in part on an indicated building), the routine continues instead to block 520, where it obtains indications of one or more search criteria to use, such as from current user selections or as indicated in the information or instructions received in block 505, and then searches stored information about buildings to determine one or more of the buildings that satisfy the search criteria or otherwise obtains indications of one or more such matching buildings. In the illustrated embodiment, the routine then further selects a best match target building from the one or more returned buildings (e.g., the returned other building with the highest similarity or other matching rating for the specified criteria, or using another selection technique indicated in the instructions or other information received in block 505), while in other embodiments the routine may instead present multiple candidate buildings that satisfy the search criteria (e.g., in a ranked order based on degree of match) and receive a user selection of the target building from the multiple candidates.

After blocks 520 or 525, the routine continues to block 535 to retrieve a floor plan for the target building and/or other generated mapping information for the building (e.g., a group of inter-linked images for use as part of a virtual tour), and optionally indications of associated linked information for the building interior and/or a surrounding location external to the building, and/or information about one or more generated explanations or other descriptions of why the target building is selected as matching specified criteria (e.g., based in part or in whole on one or more other indicated buildings), and selects an initial view of the retrieved information (e.g., a view of the floor plan, a particular room shape, a particular image, etc., optionally along with generated explanations or other descriptions of why the target building is selected to be matching if such information is available). In block 540, the routine then displays or otherwise presents the current view of the retrieved information, and waits in block 545 for a user selection. After a user selection in block 545, if it is determined in block 550 that the user selection corresponds to adjusting the current view for the current target building (e.g., to change one or more aspects of the current view), the routine continues to block 555 to update the current view in accordance with the user selection, and then returns to block 540 to update the displayed or otherwise presented information accordingly. The user selection and corresponding updating of the current view may include, for example, displaying or otherwise presenting a piece of associated linked information that the user selects (e.g., a particular image associated with a displayed visual indication of a determined acquisition location, such as to overlay the associated linked information over at least some of the previous display; a particular other image linked to a current image and selected from the current image using a user-selectable control overlaid on the current image to represent that other image; etc.), and/or changing how the current view is displayed (e.g., zooming in or out; rotating information if appropriate; selecting a new portion of the floor plan to be displayed or otherwise presented, such as with some or all of the new portion not being previously visible, or instead with the new portion being a subset of the previously visible information; etc.). If it is instead determined in block 550 that the user selection is not to display further information for the current target building (e.g., to display information for another building, to end the current display operations, etc.), the routine continues instead to block 595, and returns to block 505 to perform operations for the user selection if the user selection involves such further operations.

If it is instead determined in block 510 that the instructions or other information received in block 505 are not to present information representing a building, the routine continues instead to block 560 to determine whether the instructions or other information received in block 505 correspond to identifying other images (if any) corresponding to one or more indicated target images, and if so continues to blocks 565-570 to perform such activities. In particular, the routine in block 565 receives the indications of the one or more target images for the matching (such as from information received in block 505 or based on one or more current interactions with a user) along with one or more matching criteria (e.g., an amount of visual overlap), and in block 570 identifies one or more other images (if any) that match the indicated target image(s), such as by interacting with the ICA and/or MIGM systems to obtain the other image(s). The routine then displays or otherwise provides information in block 570 about the identified other image(s), such as to provide information about them as part of search results, to display one or more of the identified other image(s), etc. If it is instead determined in block 560 that the instructions or other information received in block 505 are not to identify other images corresponding to one or more indicated target images, the routine continues instead to block 575 to determine whether the instructions or other information received in block 505 correspond to obtaining and providing guidance acquisition instructions during an image acquisition session with respect to one or more indicated target images (e.g., a most recently acquired image), and if so continues to block 580, and otherwise continues to block 590. In block 580, the routine obtains information about guidance acquisition instructions of one or more types, such as by interacting with the ICA system, and displays or otherwise provides information in block 580 about the guidance acquisition instructions, such as by overlaying the guidance acquisition instructions on a partial floor plan and/or recently acquired image in manners discussed in greater detail elsewhere herein.

In block 590, the routine continues instead to perform other indicated operations as appropriate, such as to configure parameters to be used in various operations of the system (e.g., based at least in part on information specified by a user of the system, such as a user of a mobile device who acquires one or more building interiors, an operator user of the BIMM and/or MIGM systems, etc., including for use in personalizing information display for a particular user in accordance with his/her preferences), to obtain and store other information about users of the system, to respond to requests for generated and stored information, to perform any housekeeping tasks, etc.

Following blocks 509 or 570 or 580 or 590, or if it is determined in block 550 that the user selection does not correspond to the current building, the routine proceeds to block 595 to determine whether to continue, such as until an explicit indication to terminate is received, or instead only if an explicit indication to continue is received. If it is determined to continue (including if the user made a selection in block 545 related to a new building to present), the routine returns to block 505 to await additional instructions or information (or to continue directly on to block 535 if the user made a selection in block 545 related to a new building to present), and if not proceeds to step 599 and ends.

As noted above, if an ICA system is included and used in a particular embodiment, it may perform automated operations to acquire images (e.g., panorama images) at various acquisition locations associated with a building (e.g., in the interior of multiple rooms of the building), and optionally further acquire metadata related to the image acquisition process (e.g., compass heading data, GPS location data, etc.) and/or to movement of a capture device between acquisition locations-in at least some embodiments, such acquisition and subsequent use of acquired information may occur without having or using information from depth sensors or other distance-measuring devices about distances from images' acquisition locations to walls or other objects in a surrounding building or other structure. For example, in at least some such embodiments, such techniques may include using one or more mobile devices (e.g., a camera having one or more fisheye lenses and mounted on a rotatable tripod or otherwise having an automated rotation mechanism; a camera having one or more fisheye lenses sufficient to capture 360 degrees horizontally without rotation; a smart phone held in a constant position relative to a user (e.g., chest height, eye height, etc.) and moved by the user, such as to rotate the user's body and held smart phone in a 360° circle around a vertical axis; a camera held by or mounted on a user or the user's clothing; a camera mounted on an aerial and/or ground-based drone or other robotic device; etc.) to capture visual data from a sequence of multiple acquisition locations within multiple rooms of a house (or other building).

As is also noted above, if a MIGM system is included and used in a particular embodiment, it may perform automated operations to analyze multiple 360° panorama images and/or other images that have been acquired for a building interior (and optionally an exterior of the building), and determine room shapes and locations of passages connecting rooms for some or all of those panorama images, as well as to determine wall elements and other elements of some or all rooms of the building in at least some embodiments and situations. The types of connecting passages between two or more rooms may include one or more of doorway openings and other inter-room non-doorway wall openings, windows, stairways, non-room hallways, etc., and the automated analysis of the images may identify such elements based at least in part on identifying the outlines of the passages, identifying different content within the passages than outside them (e.g., different colors or shading), etc. The automated operations may further include using the determined information to generate a floor plan for the building and to optionally generate other mapping information for the building, such as by using the inter-room passage information and other information to determine relative positions of the associated room shapes to each other, and to optionally add distance scaling information and/or various other types of information to the generated floor plan. In addition, the MIGM system may in at least some embodiments perform further automated operations to determine and associate additional information with a building floor plan and/or specific rooms or locations within the floor plan, such as to analyze images and/or other environmental information (e.g., audio) captured within the building interior to determine particular attributes (e.g., a color and/or material type and/or other characteristics of particular features or other elements, such as a floor, wall, ceiling, countertop, furniture, fixture, appliance, cabinet, island, fireplace, etc. ; the presence and/or absence of particular features or other elements; etc.), or to otherwise determine relevant attributes (e.g., directions that building features or other elements face, such as windows; views from particular windows or other locations; etc.).

In some embodiments and situations, an adjacency graph may also be generated that represents information about room adjacencies for a building and that further stores or otherwise includes some or all such data for the building, such as from analysis of a floor plan and with at least some such data stored in or otherwise associated with nodes of the adjacency graph that represent some or all rooms of the floor plan (e.g., with each node containing information about attributes of the room represented by the node), and/or with at least some such attribute data stored in or otherwise associated with edges between nodes that represent connections between adjacent rooms via doorways or other non-doorway inter-room wall openings, or in some situations further represent adjacent rooms that share at least a portion of at least one wall and optionally a full wall without any direct inter-room opening connecting those two rooms (e.g., with each edge containing information about connectivity status between the rooms represented by the nodes that the edge inter-connects, such as whether an inter-room opening exists between the two rooms, and/or a type of inter-room opening or other type of adjacency between the two rooms such as without any direct inter-room wall opening connection). In some embodiments and situations, the floor plan and/or adjacency graph may further represent at least some information external to the building, such as exterior areas adjacent to doorways or other wall openings between the building and the exterior and/or other accessory structures on the same property as the building (e.g., a garage, shed, pool house, separate guest quarters, mother-in-law unit or other accessory dwelling unit, pool, patio, deck, sidewalk, garden, yard, etc.), or more generally some or all external areas of a property that includes one or more buildings (e.g., a house and one or more outbuildings or other accessory structures)—such exterior areas and/or other structures may be represented in various manners in the adjacency graph and/or on the floor plan, such as via separate nodes for each such exterior area or other structure in the adjacency graph or by placing the floor plan on a representation of the property that includes the external areas, or instead as attribute information associated with corresponding nodes or edges of the adjacency graph or instead with the adjacency graph as a whole (for the building as a whole). The adjacency graph may further have associated attribute information for the corresponding rooms and inter-room connections in at least some embodiments, such as to represent within the adjacency graph some or all of the information available on a floor plan and otherwise associated with the floor plan (or in some embodiments and situations, information in and associated with a 3D model of the building)—for example, if there are images associated with particular rooms of the floor plan or other associated areas (e.g., external areas), corresponding visual attributes may be included within the adjacency graph, whether as part of the associated rooms or other areas, or instead as a separate layer of nodes within the graph that represent the images. In embodiments with adjacency information in a form other than an adjacency graph, some or all of the above-indicated types of information may be stored in or otherwise associated with the adjacency information, including information about rooms, about adjacencies between rooms, about connectivity status between adjacent rooms, about attributes of the building, etc. Additional details are included below regarding the generation and use of floor plans and/or adjacency graphs, including with respect to the examples of FIGS. 2D-2H and their associated descriptions.

In addition, automated operations of a MIGM system may further include generating and using one or more vector-based embeddings (also referred to herein as a “vector embedding”) to concisely represent information in an adjacency graph for a floor plan of a building, such as to summarize the semantic meaning and spatial relationships of the floor plan in a manner that enables reconstruction of some or all of the floor plan from the vector embedding. Such a vector embedding may be generated in various manners in various embodiments, such as via the use of representation learning and one or more trained machine learning models, and in at least some such embodiments may be encoded in a format that is not easily discernible to a human reader. Non-exclusive examples of techniques for generating such vector embeddings are included in the following documents, which are incorporated herein by reference in their entirety: “Symmetric Graph Convolution Autoencoder For Unsupervised Graph Representation Learning” by Jiwoong Park et al., 2019 International Conference On Computer Vision, Aug. 7, 2019; “Inductive Representation Learning On Large Graphs” by William L Hamilton et al., 31^{st} Conference On Neural Information Processing Systems 2017, Jun. 7, 2017; and “Variational Graph Auto-Encoders” by Thomas N. Kipf et al., 30^{th} Conference On Neural Information Processing Systems 2017 (Bayesian Deep Learning Workshop), Nov. 21, 2016.

As noted above, a floor plan may have various information that is associated with individual rooms and/or with inter-room connections and/or with a corresponding building and/or encompassing property as a whole, and the corresponding adjacency graph and/or vector embedding(s) for such a floor plan may include some or all such associated information (e.g., represented as attributes of nodes for rooms in an adjacency graph and/or attributes of edges for inter-room connections in an adjacency graph and/or represented as attributes of the adjacency graph as a whole, such as in a node representing the overall building, and with corresponding information encoded in the associated vector embedding(s)). Such associated information may include a variety of types of data, including information about one or more of the following non-exclusive examples: room types, room dimensions, locations of windows and doors and other inter-room openings in a room, room shape, a view type for each exterior window, information about and/or copies of images taken in a room, information about and/or copies of audio or other data captured in a room, information of various types about features of one or more rooms (e.g., as automatically identified from analysis of images, as supplied by operator users of the BIMM system and/or by end-users viewing information about the floor plan and/or by operator users of ICA and/or MIGM systems as part of capturing information about a building and generating a floor plan for the building, etc.), attributes of structures and objects (e.g., colors, shapes, materials, age, condition, quality, etc.), types of inter-room connections, dimensions of inter-room connections, etc. Furthermore, in at least some embodiments, one or more additional subjective attributes may be determined for and associated with the floor plan, such as via analysis of the floor plan information (e.g., an adjacency graph for the floor plan) by one or more trained machine learning models (e.g., classification neural network models) to identify floor plan characteristics for a building as a whole or a particular building floor (e.g., an open floor plan; a typical/normal versus atypical/odd/unusual floor plan; a standard versus nonstandard floor plan; a floor plan that is accessibility friendly, such as by being accessible with respect to one or more characteristics such as disability and/or advanced age; etc.)—in at least some such embodiments, the one or more classification neural network models are part of the BIMM system and are trained via supervised learning using labeled data that identifies floor plans having each of the possible characteristics, while in other embodiments such classification neural network models may instead use unsupervised clustering.

After an adjacency graph and one or more vector embeddings are generated for a floor plan and associated information of a building, that generated information may be used as specified criteria to automatically determine one or more other similar or otherwise matching floor plans of other buildings in various manners in various embodiments. For example, in some embodiments, an initial floor plan is identified, and one or more corresponding vector embeddings for the initial floor plan are generated and compared to generated vector embeddings for other candidate floor plans in order to determine a difference between the initial floor plan's vector embedding(s) and the vector embeddings of some or all of the candidate floor plans, with smaller differences between two vector embeddings corresponding to higher degrees of similarity between the building information represented by those vector embeddings. Differences between two such vector embeddings may be determined in various manners in various embodiments, including, as non-exclusive examples, by using one or more of the following distance metrics: Euclidean distance, cosine distance, graph edit distance, a custom distance measure specified by a user, etc.; and/or otherwise determining similarity without use of such a distance metrics. In at least some embodiments, multiple such initial floor plans may be identified and used in the described manner to determine a combined distance between a group of vector embeddings for the multiple initial floor plans and the vector embeddings for each of multiple other candidate floor plans, such as by determining individual distances for each of the initial floor plans to a given other candidate floor plan and by combining the multiple individual determined distances in one or more manners (e.g., a mean or other average, a cumulative total, etc.) to generate the combined distance for the group of vector embeddings of the multiple initial floor plans to that given other candidate floor plan.

Furthermore, in some embodiments, one or more explicitly specified criteria other than one or more initial floor plans are received (whether in addition to or instead of receiving one or more initial floor plans), and the corresponding vector embedding(s) for each of multiple candidate floor plans are compared to information generated from the specified criteria in order to determine which of the candidate floor plans satisfy the specified criteria (e.g., are a match above a defined similarity threshold), such as by generating a representation of a building that corresponds to the criteria (e.g., has attributes identified in the criteria) and generating one or more vector embeddings for the building representation for use in vector embedding comparisons in the manners discussed above. The specified criteria may be of various types in various embodiments and situations, such as one or more of the following non-exclusive examples: search terms corresponding to specific attributes of rooms and/or inter-room connections and/or buildings as a whole (whether objective attributes that can be independently verified and/or replicated, and/or subjective attributes that are determined via use of corresponding classification neural networks); information identifying adjacency information between two or more rooms or other areas; information about views available from windows or other exterior openings of the building; information about directions of windows or other structural features or other elements of the building (e.g., such as to determine natural lighting information available via those windows or other structural elements, optionally at specified days and/or seasons and/or times); etc. Non-exclusive illustrative examples of such specified criteria include the following: a bathroom adjacent to bedroom (e.g., without an intervening hall or other room); a deck adjacent to a family room (optionally with a specified type of connection, such as French doors); 2 bedrooms facing south; a kitchen with a tile-covered island and a northward-facing view; a master bedroom with a view of the ocean or more generally of water; any combination of such specified criteria; etc. In addition, in some embodiments, one or more target floor plans are identified that are similar to specified criteria associated with a particular end-user (e.g., based on one or more initial target floor plans that are selected by the end-user and/or are identified as previously being of interest to the end-user, whether based on explicit and/or implicit activities of the end-user to specify such floor plans; based on one or more search criteria specified by the end-user, whether explicitly and/or implicitly; etc.), and are used in further automated activities to personalize interactions with the end-user. Such further automated personalized interactions may be of various types in various embodiments, and in some embodiments may include displaying or otherwise presenting information to the end-user about the target floor plan(s) and/or additional information associated with those floor plans.

The described techniques may further include additional operations in some embodiments. For example, in at least some embodiments, machine learning techniques may be used to learn the attributes and/or other characteristics of adjacency graphs to encode in corresponding vector embeddings that are generated, such as the attributes and/or other characteristics that best enable subsequent automated identification of building floor plans having attributes satisfying target criteria (e.g., number of bedrooms; number of bathrooms; connectivity between rooms; size and/or dimensions of each room; number of windows/doors in each room; types of views available from exterior windows, such as water, mountain, a back yard or other exterior area of the property, etc. ; location of windows/doors in each room; etc.). In addition, in at least some embodiments, machine learning techniques may be used to identify objects of one or more types in one or more images (e.g., doorways, kitchen cabinets, etc.), such as by one or more machine learning models trained to determine such information (e.g., a machine learning model specific to each defined object type). Furthermore, in at least some embodiments, machine learning techniques may be used to determine an estimated camera height for one or more images, such as by one or more machine learning models trained to determine such information (e.g., a machine learning model specific to each defined object type).

Aspects of the present disclosure are described herein with reference to flowchart illustrations and/or block diagrams of methods, apparatus (systems), and computer program products according to embodiments of the present disclosure. It will be appreciated that each block of the flowchart illustrations and/or block diagrams, and combinations of blocks in the flowchart illustrations and/or block diagrams, can be implemented by computer readable program instructions. It will be further appreciated that in some implementations the functionality provided by the routines discussed above may be provided in alternative ways, such as being split among more routines or consolidated into fewer routines. Similarly, in some implementations illustrated routines may provide more or less functionality than is described, such as when other illustrated routines instead lack or include such functionality respectively, or when the amount of functionality that is provided is altered. In addition, while various operations may be illustrated as being performed in a particular manner (e.g., in serial or in parallel, or synchronous or asynchronous) and/or in a particular order, in other implementations the operations may be performed in other orders and in other manners. Any data structures discussed above may also be structured in different manners, such as by having a single data structure split into multiple data structures and/or by having multiple data structures consolidated into a single data structure. Similarly, in some implementations illustrated data structures may store more or less information than is described, such as when other illustrated data structures instead lack or include such information respectively, or when the amount or types of information that is stored is altered.

From the foregoing it will be appreciated that, although specific embodiments have been described herein for purposes of illustration, various modifications may be made without deviating from the spirit and scope of the invention. Accordingly, the invention is not limited except as by corresponding claims and the elements recited by those claims. In addition, while certain aspects of the invention may be presented in certain claim forms at certain times, the inventors contemplate the various aspects of the invention in any available claim form. For example, while only some aspects of the invention may be recited as being embodied in a computer-readable medium at particular times, other aspects may likewise be so embodied.

1. A computer-implemented method comprising:
receiving, by one or more computing devices and from a user, a source image captured at an acquisition location in a room of a house, and information about an indicated object to be added to a modified version of the source image, the information about the indicated object including an image of the indicated object and including height and width and length sizes of the indicated object,
obtaining, by the one or more computing devices, a house floor plan having dimensions of the room and a position within the room of the acquisition location;
determining, by the one or more computing devices and based at least in part on the dimensions of the room and the position within the room of the acquisition location, dimensions within the source image of portions of a floor and one or more walls of the room that are visible in the source image;
determining, by the one or more computing devices and based on the determined dimensions within the source image of the portions of the floor and the one or more walls, a three-dimensional geometrical shape with a size and shape within the source image that match the height and width and length sizes of the indicated object, and an orientation of the three-dimensional geometrical shape to match positioning of the floor and at least one of the walls within the source image;
determining, by the one or more computing devices, contiguous locations within the source image at which to place the indicated object, including receiving input from the user to position the three-dimensional geometrical shape on the floor of the room within the source image without changing the size or the shape or the orientation of the three-dimensional geometrical shape;
generating, by the one or more computing devices, a conditional control image to use in generating the modified version of the source image, the conditional control image being the source image with a binary pixel mask that is added at the determined contiguous locations within the source image and that blocks original pixels of the source image according to the size and the shape and the orientation of the three-dimensional geometrical shape;
generating, by the one or more computing devices, the modified version of the source image with the added indicated object being inpainted in place of the binary pixel mask in the conditional control image, including supplying, as input to a ControlNet diffusion model trained to use pairs of images each including an image with a binary pixel mask to be replaced with another image of an object, the trained ControlNet diffusion model being a trained machine learning model. the conditional control image and the image of the indicated object and instructions to replace the binary pixel mask in the conditional control image to be replaced with the indicated object; and
presenting, by the one or more computing devices, the generated modified version of the source image with the added indicated object.

2. The computer-implemented method of claim 1 further comprising, for each of one or more additional images of the room having visual data showing a same position of the room as the determined contiguous locations within the source image, generating a modified version of that additional image with the indicated object added at additional determined contiguous locations within that additional image for the same position of the room, including:
adding, by the one or more computing devices and at the same position of the room, a representation to the floor plan of the size and shape and orientation of the three-dimensional geometrical shape; and
for each of the one or more additional images,
determining, by the one or more computing devices and using the representation added to the floor plan, the additional contiguous locations within that additional image;
generating, by the one or more computing devices, an additional conditional control image to use in generating the modified version of that additional image, the additional conditional control image being that additional image with an additional binary pixel mask that is added at the determined additional contiguous locations within that additional image;
generating, by the one or more computing devices, the modified version of that additional image with the added indicated object being inpainted in place of the additional binary pixel mask in the additional conditional control image, including supplying, as input to the ControlNet diffusion model, the additional conditional control image and the image of the indicated object and instructions to replace the additional binary pixel mask in the additional conditional control image with the indicated object; and
providing, by the one or more computing devices, the generated modified version of that additional image with the added indicated object.

3. The computer-implemented method of claim 1 wherein the determining of the dimensions within the source image, and the determining of the three-dimensional geometrical shape, and the determining of the contiguous locations, and the generating of the conditional control image, and the generating of the modified version of the source image are performed without using a three-dimensional model of the indicated object.

4. A computer-implemented method comprising:
obtaining, by one or more computing devices, a source image captured at an acquisition location in a room of a building, a floor plan of the building having dimensions of the room and a position within the room of the acquisition location, and information about an indicated object to be added to a modified version of the source image, the information about the indicated object including height and width and length sizes of the indicated object and including a further image of the object;
determining, by the one or more computing devices and based at least in part on the dimensions of the room and the position within the room of the acquisition location, dimensions within the source image of portions of a floor and one or more walls of the room that are visible in the source image;
determining, by the one or more computing devices and based on the determined dimensions within the source image of the portions of the floor and the one or more walls, a size and shape of a group of pixels within the source image to match the height and width and length sizes of the indicated object;
determining, by the one or more computing devices, contiguous locations within the source image at which to place the indicated object based on positioning the group of pixels of the determined size and shape within the source image;
generating, by the one or more computing devices, a conditional control image to use in generating the modified version of the source image, the conditional control image having a size and shape of the source image and including a binary pixel mask at the determined contiguous locations within the source image and corresponding to original pixels of the source image in the determined size and shape;
generating, by the one or more computing devices, the modified version of the source image with the indicated object being added at a position in the source image of the binary pixel mask in the conditional control image, including supplying, as input to a diffusion model trained to use an indicated pixel mask corresponding to pixels in a first image that are to be replaced with a visualization of an object, the source image and the conditional control image and the further image of the indicated object, wherein the trained diffusion model is a trained machine learning model; and
presenting, by the one or more computing devices, the generated modified version of the source image with the added indicated object.

5. The computer-implemented method of claim 4 further comprising, for each of one or more additional images of the room having visual data showing a same position of the room as the determined contiguous locations within the source image, generating a modified version of that additional image with the indicated object added at additional determined contiguous locations within that additional image for the same position of the room, including:
adding, by the one or more computing devices and at the same position of the room, a representation to the floor plan of the size and shape to match the height and width and length sizes of the indicated object; and
for each of the one or more additional images,
determining, by the one or more computing devices and using the representation added to the floor plan, the additional contiguous locations within that additional image;
generating, by the one or more computing devices, an additional conditional control image to use in generating the modified version of that additional image, the additional conditional control image being that additional image with an additional binary pixel mask that is added at the determined additional contiguous locations within that additional image;
generating, by the one or more computing devices, the modified version of that additional image with the indicated object being added in place of the additional binary pixel mask in the additional conditional control image, including supplying, as input to the trained diffusion model, the additional conditional control image and the further image of the indicated object and instructions to replace the additional binary pixel mask in the additional conditional control image with the indicated object; and
providing, by the one or more computing devices, the generated modified version of that additional image with the added indicated object.

6. The computer-implemented method of claim 4 further comprising receiving, from a user, information about the indicated object, and wherein the determining of the contiguous locations within the source image at which to place the indicated object includes receiving input from the user to position the group of pixels of the determined size and shape within the source image.

7. The computer-implemented method of claim 4 wherein the positioning of the group of pixels of the determined size and shape within the source image further includes positioning a three-dimensional geographical shape having the determined size and shape and further having an orientation based on additional orientations in the source image of the portions of the floor and the one or more walls.

8. The computer-implemented method of claim 4 wherein the obtaining of the information about the indicated object including the height and the width and the length sizes of the indicated object includes analyzing, by the one or more computing devices, visual data of the further image to identify a unique type of the object, and retrieving stored size information associated with the unique type of the object.

9. The computer-implemented method of claim 4 wherein the trained diffusion model uses a ControlNet architecture, and wherein the method further comprises, before the generating of the modified version of the source image, training the diffusion model using groups of conditioning images each including an image with a pixel mask representing original image pixels to be replaced with a visualization of an object, the training including generating a plurality of the groups of the conditioning images and supplying the plurality of groups of the conditioning images to train a duplicated part of an encoder portion of a pretrained diffusion model.

10. The computer-implemented method of claim 4 wherein the binary pixel mask uses values of zero or one, wherein the generating of the conditional control image further includes adding an additional non-binary pixel mask using values between zero and one around at least a portion of the binary pixel mask to cause original pixels of the source image corresponding to the additional non-binary pixel mask to be replaced in the generated modified version of the source image with shaded versions of those original pixels that reflect one or more illumination sources within the source image.

11. The computer-implemented method of claim 10 wherein the generating of the modified version of the source image further includes providing, as part of additional conditioning information supplied as input to the trained diffusion model, information about one or more illumination sources that provide illumination in the source image to further cause shading of at least the original pixels of the source image that correspond to the additional non-binary pixel mask.

12. The computer-implemented method of claim 4 wherein the generating of the modified version of the source image further includes providing, as part of additional conditioning information supplied as input to the trained diffusion model, an image with an overlay to show positions of at least structural elements visible in the source object.

13. The computer-implemented method of claim 4 wherein the conditional control image is the source image with the binary pixel mask overlaid to block the original pixels of the source image at the determined contiguous locations, and wherein the determining of the dimensions within the source image, and the determining of the size and shape of the group of pixels, and the determining of the contiguous locations, and the generating of the conditional control image, and the generating of the modified version of the source image are performed without using a three-dimensional model of the indicated object.

14. The computer-implemented method of claim 4 further comprising determining the size and shape of the group of pixels to represent an outline of the indicated object and an interior of the outline, the outline of the object being a non-uniform shape that is not a geometrical shape, and wherein the positioning of the group of pixels of the determined size and shape within the source image is performed to at least one of cover an existing object on a floor of the room that is visible in the source image or to cover an empty space in the room.

15. A system comprising:
one or more hardware processors of one or more computing devices; and
one or more memories with stored instructions that, when executed by at least one of the one or more hardware processors, cause at least one computing device of the one or more computing devices to perform automated operations including at least:
obtaining a source image captured at an acquisition location in a room of a building, first information about the room including dimensions of the room and a position within the room of the acquisition location, and second information about an indicated object to be added to a modified version of the source image, the second information about the indicated object including height and width and length sizes of the indicated object and including a further image of the object;
determining, based at least in part on the dimensions of the room and the position within the room of the acquisition location, dimensions within the source image of structural elements of the room that are visible in the source image;
determining, based on the determined dimensions within the source image of the structural elements of the room, a size and shape of a group of pixels within the source image to match the height and width and length sizes of the indicated object;
determining a location within the source image at which to place the indicated object based on positioning the group of pixels of the determined size and shape within the source image;
generating conditioning information to use in generating the modified version of the source image that includes a first image, the first image having a size and shape of the source image and with a pixel mask at the determined location to block the determined size and shape of pixels of the source image;
generating the modified version of the source image with the indicated object being added in place of the pixel mask in the first image, including supplying, as input to a trained diffusion model, at least the first image and the further image of the indicated object to cause original pixels of the source image corresponding to the pixel mask in the first image to be replaced with the indicated object, wherein the trained diffusion model is a trained machine learning model; and
providing the generated modified version of the source image with the added indicated object.

16. The system of claim 15 wherein the structural elements of the room visible in the source image include at least one of a wall or a window or a doorway of a room of the building, wherein the stored instructions include software instructions that, when executed by the at least one hardware processor, cause the at least one computing device to perform further automated operations including obtaining a floor plan of the building having the dimensions of the room and the position within the room of the acquisition location, the dimensions of the room including one or more dimensions of the at least one of the wall or the window or the doorway of the room, and wherein the determining of the dimensions within the source image of the structural elements of the building visible in the source image includes using the one or more dimensions of the at least one of the wall or the window or the doorway of the room and the position within the room of the acquisition location from the floor plan.

17. The system of claim 15 wherein the first image is the source image with the pixel mask overlaid to block original pixels of the source image at the determined location of the determined size and shape, and wherein the generating of the modified version of the source image with the added indicated object further includes supplying the first image as a conditional control image to the trained diffusion model along with the further image, to cause a generated visual representation of the indicated object to replace the original pixels of the source image blocked by the pixel mask in the first image.

18. The system of claim 15 wherein the structural elements of the building visible in the source image include at least a floor and a wall of the room, wherein the group of pixels further includes an orientation to match orientations within the source image of the floor and the wall, and wherein the positioning of the group of pixels within the source image includes using the orientation to position the group of pixels on the floor of the room and along the wall of the room.

19. The system of claim 18 wherein the automated operations further include receiving, from a user, the second information and an indication of the source image, wherein the determining of the location within the source image at which to place the indicated object includes receiving input from the user to position the group of pixels of the determined size and shape within the source image, and wherein the providing of the generated modified version of the source image with the added indicated object includes presenting, to the user, the generated modified version of the source image with the added indicated object.

20. A non-transitory computer-readable medium having stored contents that cause one or more computing devices to perform automated operations, the automated operations including at least:
obtaining, by the one or more computing devices, a source image captured at an acquisition location at a building, and information about three-dimensional sizes of an indicated type of object to be added to a modified version of the source image;
determining, by the one or more computing devices, dimensions within the source image of structural elements of the building visible in the source image;
determining, by the one or more computing devices and based on the determined dimensions within the source image of the structural elements, a size and shape of a group of pixels within the source image to match the three-dimensional sizes of the indicated type of object;
determining, by the one or more computing devices, a location within the source image at which to place the indicated type of object;
generating, by the one or more computing devices, conditioning information to use in generating the modified version of the source image that includes a first image, the first image having a size and shape of the source image and having a pixel mask at the determined location to represent the added object blocking the determined size and shape of original pixels of the source image;
generating, by the one or more computing devices, the modified version of the source image with an added object of the indicated type of object, including supplying, as input to a trained diffusion model, at least the first image to cause the pixel mask to be replaced with an image of the added object, wherein the trained diffusion model is a trained machine learning model; and
providing, by the one or more computing devices, the generated modified version of the source image with the added object.

21. The non-transitory computer-readable medium of claim 20 wherein the structural elements of the building visible in the source image include at least one wall of a room of the building, wherein the stored contents include software instructions that, when executed by the one or more computing devices, cause the one or more computing devices to perform further automated operations including obtaining a floor plan of the building having one or more dimensions of the at least one wall of the room and a position within the room of the acquisition location, and wherein the determining of the dimensions within the source image of the structural elements of the building visible in the source image includes using the one or more dimensions of the at least one wall of the room and the position within the room of the acquisition location from the floor plan.

22. The non-transitory computer-readable medium of claim 20 wherein the obtaining of the information about the three-dimensional sizes of the indicated type of object includes receiving an additional image of an instance of the indicated type of object, and wherein the generating of the modified version of the source image with the added object of the indicated type of object further includes supplying, to the trained diffusion model, the source image, and the first image as a conditional control image, and the additional image to use in replacing the original pixels of the source image corresponding to the pixel mask with the image of the added object, and one or more prompt instructions.

23. The non-transitory computer-readable medium of claim 20 wherein the structural elements of the building visible in the source image include at least a floor of a room of the building and a wall of the room, and wherein the determining of the dimensions within the source image of the structural elements of the building visible in the source image includes analyzing, by the one or more computing devices, data of the source image, the analyzing of the data of the source image including at least one of analyzing visual data of the source image to identify an object of known size and to determine a quantity of pixels of the source image associated with the identified object, or analyzing depth data associated with the source image to determine distances from the acquisition location to the structural elements of the building visible in the source image.

24. The non-transitory computer-readable medium of claim 20 wherein the structural elements of the building visible in the source image include at least a floor of a room of the building and a wall of the room, wherein the group of pixels further includes an orientation to match the floor and the wall within the source image, and wherein the determining of the location within the source image includes using the orientation to position the group of pixels on the floor of the room and along the wall of the room.

25. The non-transitory computer-readable medium of claim 24 wherein the automated operations further include receiving, by the one or more computing devices and from a user, the additional image and the information about the three-dimensional sizes of the indicated type of object, wherein the determining of the location within the source image at which to place the indicated type of object includes receiving input from the user to position the group of pixels of the determined size and shape within the source image, and wherein the providing of the generated modified version of the source image with the added object includes presenting, by the one or more computing devices and to the user, the generated modified version of the source image with the added object.
